(19) United States
(12) Patent Application Publication
(10) Pub. No.: US 2026/0007002 A1
(43) Pub. Date: Jan. 1, 2026

(54) DISPLAY PANEL, ELECTRONIC DEVICE INCLUDING THE SAME AND MANUFACTURING METHOD OF THE DISPLAY PANEL

(71) Applicant: Samsung Display Co., Ltd., Yongin-si (KR)

(72) Inventors: SEUL-KI KIM, Yongin-si (KR); YU-JIN KIM, Yongin-si (KR); JEONGJU PARK, Yongin-si (KR); ILBAE AHN, Yongin-si (KR); KAP SOO YOON, Yongin-si (KR); HANHEE YOON, Yongin-si (KR)

(21) Appl. No.: 19/253,538

(22) Filed: Jun. 27, 2025

(30) Foreign Application Priority Data
Jul. 1, 2024 (KR) 10-2024-0086377

(51) Int. Cl. H10K 59/122; H10K 59/12

(52) U.S. Cl. CPC H10K 59/122; H10K 59/1201

(57) ABSTRACT

A display panel including a base substrate including a pixel region and a peripheral region adjacent to the pixel region, a circuit layer on the base substrate, and a display element layer on the circuit layer, wherein the display element layer includes an inorganic layer having a first pixel opening overlapping the pixel region, a pixel-defining film comprising a second pixel opening corresponding to the first pixel opening and a peripheral opening overlapping the peripheral region, and at least a portion of the pixel defining film is on the inorganic layer, and a light-emitting element including a first electrode under the inorganic layer and at least an upper portion of an upper surface of the light-emitting element is exposed by the first pixel opening, a functional layer in the first pixel opening and the second pixel opening, and a second electrode on the functional layer.

### CROSS-REFERENCE TO RELATED APPLICATIONS

The present application claims priority to and the benefit of Korean Patent Application No. 10-2024-0086377, filed on Jul. 1, 2024, the entire disclosure of which is hereby incorporated by reference.

### BACKGROUND

### 1. Field

Embodiments of the present disclosure described herein are related to a display panel and a manufacturing method of the display panel, and for example, to a display panel with (having) improved light emission quality and color reproducibility and a manufacturing method of the display panel.

### 2. Description of Related Art

Electronic device (e.g., multimedia electronic devices), such as televisions, mobile phones, tablet computers, navigation devices, and/or game consoles, may include a display configured to show images. These devices typically contain a plurality of pixels, each including a light-emitting element that generates light and a driving element connected to the light-emitting element.

Electronic devices incorporating organic light-emitting elements (OLEDs) are considered next-generation devices due to their wide viewing angles, high response speeds, and low power consumption. However, as the size of the display area increases, the stability of the supplied voltage may deteriorate, potentially leading to non-uniform luminance.

The information disclosed in this Background section is intended to enhance understanding of the background of the disclosure and therefore it may contain information that does not constitute prior art.

### SUMMARY

Aspects according to one or more embodiments of the present disclosure are directed toward a display panel capable of providing high resolution and improved color reproducibility, as well as a manufacturing method of the display panel.

Additional aspects will be set forth in part in the description which follows and, in part, will be apparent from the description, or may be learned by practice of the presented embodiments of the disclosure.

In one or more embodiments of the present disclosure, a display panel may include a base substrate including a pixel region and a peripheral region adjacent to the pixel region, a circuit layer arranged on the base substrate, and a display element layer arranged on the circuit layer, wherein the display element layer includes an inorganic layer having a first pixel opening overlapping the pixel region, a pixel-defining film including a second pixel opening corresponding to the first pixel opening and a peripheral opening overlapping the peripheral region, and at least a portion of the pixel-defining film is arranged on the inorganic layer, and a light-emitting element including a first electrode under the inorganic layer and at least a portion of an upper surface of the light-emitting element is exposed by the first pixel opening, a functional layer arranged in the first pixel opening and the second pixel opening, and a second electrode arranged on the functional layer, wherein the pixel-defining film includes an upper surface, a first side surface extending from the upper surface and defining the second pixel opening, and a second side surface opposite to the first side surface and defining the peripheral opening, and at least a portion of the inorganic layer protrudes from the second side surface to an inner side of the peripheral opening.

In one or more embodiments, the functional layer may be arranged in the peripheral opening.

In one or more embodiments, at least a portion of the functional layer may be cut in the peripheral region.

In one or more embodiments, at least a portion of a side surface of the inorganic layer may be exposed by the peripheral opening.

In one or more embodiments, at least a portion of an upper surface of the circuit layer may be exposed by the peripheral opening.

In one or more embodiments, the inorganic layer may include silicon nitride.

In one or more embodiments, at least a portion of the inorganic layer may overlap the peripheral opening in a plan view.

In one or more embodiments, the pixel-defining film may include a first portion and a second portion arranged below the first portion, and the first portion and the second portion may be spaced and/or apart (e.g., spaced apart or separated) with the inorganic layer therebetween in a cross-sectional view.

In one or more embodiments, the first portion may be directly arranged on the pixel-defining film, and the second portion may be arranged on the same layer as the first electrode.

In one or more embodiments, the inorganic layer may include a protruding portion protruding from the second side surface and a flat portion arranged between the first portion and the second portion.

In one or more embodiments, the functional layer may include a first functional part overlapping the pixel region and a second functional part overlapping the peripheral region, and at least a portion of the second functional part may be cut by an air gap.

In one or more embodiments, the second functional part and the pixel-defining film may be spaced and/or apart (e.g., spaced apart or separated) from each other with the air gap therebetween.

In one or more embodiments, the pixel region may include a first pixel region and a second pixel region spaced and/or apart (e.g., spaced apart or separated) from each other with the peripheral region therebetween in a plan view, the light-emitting element may include a first light-emitting element overlapping the first pixel region and including a first functional layer and a second light-emitting element overlapping the second pixel region and including a second functional layer, the first functional layer may include a (1-1)-th functional part overlapping the first pixel region and a (1-2)-th functional part overlapping the peripheral region and extending from the (1-1)-th functional part, the second functional layer may include a (2-1)-th functional part overlapping the second pixel region and a (2-2)-th functional part overlapping the peripheral region and extending from the (2-1)-th functional part, and the (1-2)-th functional part and the (2-2)-th functional part may be spaced and/or apart (e.g., spaced apart or separated) with the air gap therebetween.

In one or more embodiments, the light-emitting element may be configured to emit source light, and the display panel may further include an optical structure layer that is arranged on the display element layer and is configured to transmit the source light or is configured to convert the source light into light of a different wavelength.

In one or more embodiments, the optical structure layer may include a light control layer including a light control pattern and a color filter arranged on the light control layer.

In one or more embodiments of the present disclosure, a manufacturing method of a display panel may include a preliminary display substrate including a base substrate including a pixel region and a peripheral region adjacent to the pixel region and a circuit layer arranged on the base substrate, forming a preliminary electrode and a first preliminary inorganic layer on the preliminary display substrate, arranging a first photoresist pattern on the first preliminary inorganic layer, forming a second preliminary inorganic layer by etching a portion of the first preliminary inorganic layer, forming a first electrode by etching a portion of the preliminary electrode, forming a preliminary pixel-defining film on the circuit layer in correspondence to the peripheral region, forming an inorganic layer by forming a first pixel opening overlapping the pixel region by etching a portion of the second preliminary inorganic layer, arranging a second photoresist pattern on the preliminary pixel-defining film, and forming a pixel-defining film by forming a peripheral opening by etching a portion of the preliminary pixel-defining film, wherein the peripheral opening exposes at least a portion of a side surface of the inorganic layer.

In one or more embodiments, the inorganic layer may include an inorganic material, and the pixel-defining film may include an organic material.

In one or more embodiments, the forming of the second preliminary inorganic layer, the forming of the inorganic layer by forming the first pixel opening, and the forming of the pixel-defining film may include a dry etching process.

In one or more embodiments, the forming of the first electrode may include a wet etching process.

### BRIEF DESCRIPTION OF THE DRAWINGS

The accompanying drawings are included to provide a further understanding of the disclosure, and are incorporated in and constitute a part of this specification.

The drawings illustrate embodiments of the disclosure and, together with the description, serve to explain principles of the disclosure. In the drawings:

FIG. 1 is a perspective view of an electronic device according to one or more embodiments;

FIG. 2A is an exploded perspective view of an electronic device according to one or more embodiments;

FIG. 2B is a cross-sectional view of a display panel according to one or more embodiments;

FIG. 3A is a plan view of a display panel according to one or more embodiments;

FIG. 3B is an equivalent circuit diagram of a pixel according to one or more embodiments;

FIG. 4 is a plan view of a portion of a display panel according to one or more embodiments;

FIGS. 5 and 6 each are a cross-sectional view of a portion of a display panel according to one or more embodiments;

FIG. 7A is an enlarged cross-sectional view of a portion of a display panel according to one or more embodiments;

FIGS. 7B and 8 each are an enlarged cross-sectional view of a portion of a display panel according to one or more embodiments;

FIG. 7C is an enlarged plan view of a portion of a display panel according to one or more embodiments;

FIG. 9 is a cross-sectional view of a light-emitting element according to one or more embodiments of the present disclosure; and

FIGS. 10A-10H are cross-sectional views illustrating some steps (e.g., acts or taks) of a manufacturing method of a display panel according to one or more embodiments.

### DETAILED DESCRIPTION

Embodiments of the present disclosure may be variously modified and have one or more suitable forms, but some embodiments will be illustrated in the drawings and described in more detail in the description. However, this is not intended to limit the present disclosure to a specific disclosed form, and it should be understood that all changes, equivalents, and alternatives included in the spirit and scope of the present disclosure are included.

In the present specification, “including A or B”, “A and/or B”, etc., represents A or B, or A and B.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b or c”, “at least one selected from a, b and c”, etc., may indicate only a, only b, only c, both (e.g., simultaneously) a and b, both (e.g., simultaneously) a and c, both (e.g., simultaneously) b and c, all of a, b, and c, or variations thereof.

In the present disclosure, it will be understood that if (e.g., when) an element (or a region, a layer, a portion, and/or the like) is referred to as being “on”, “connected to” or “coupled to” another element, it may be directly arranged on, connected or coupled to the other element, or an intervening element may be arranged therebetween.

In one or more embodiments, as used herein, the wording “directly arranged” may refer to that there is no layer, film, region, plate, and/or the like added between a portion such as a layer, film, region, or plate and another portion. For example, “directly arranged” may refer to placing two layers or two members without using an additional member such as an adhesive member therebetween.

Like reference numerals or symbols refer to like elements. Also, in the drawings, the thicknesses, ratios, and dimensions of the elements are exaggerated for effective description of the technical contents. The term “and/or” includes all of one or more combinations which may be defined by related elements.

Although the terms first, second, and/or the like. may be used herein to describe one or more suitable elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well unless the context clearly indicates otherwise.

In addition, the terms such as “below”, “on lower side”, “above”, and “on upper side” may be used herein to describe the relationships of the elements illustrated in the drawings. These terms have relative concepts and are described on the basis of the directions indicated in the drawings. As used herein, the wording “arranged on” may represent being arranged not only on an upper portion of any one member but also on a lower portion thereof.

It will be understood that the terms such as “include” or “have”, if (e.g., when) used herein, are intended to specify the presence of stated features, integers, steps, operations, elements, components, and/or one or more (e.g., any suitable) combinations thereof, but do not preclude the presence or addition of one or more other features, integers, steps, operations, elements, components, and/or one or more (e.g., any suitable) combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, an electronic device according to one or more embodiments of the present disclosure will be described with reference to the drawings.

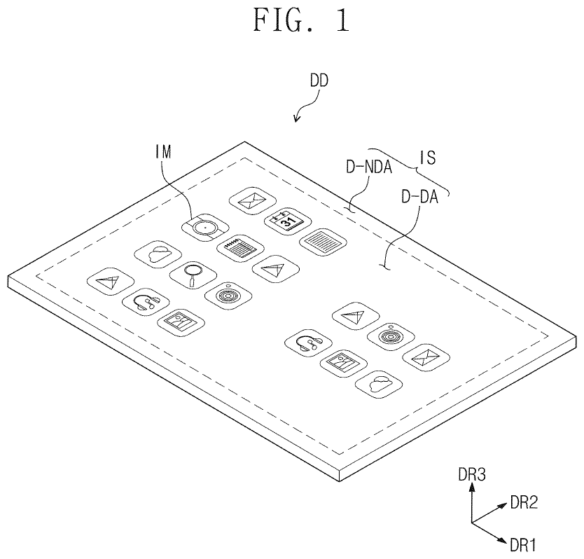

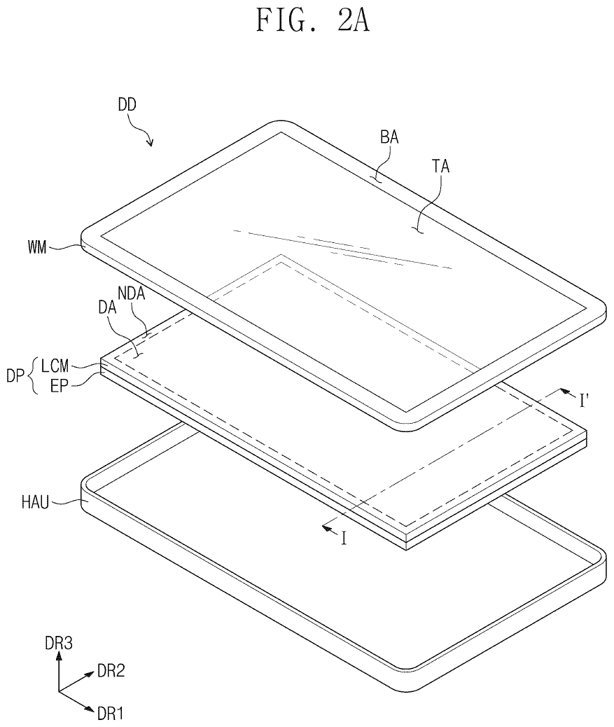

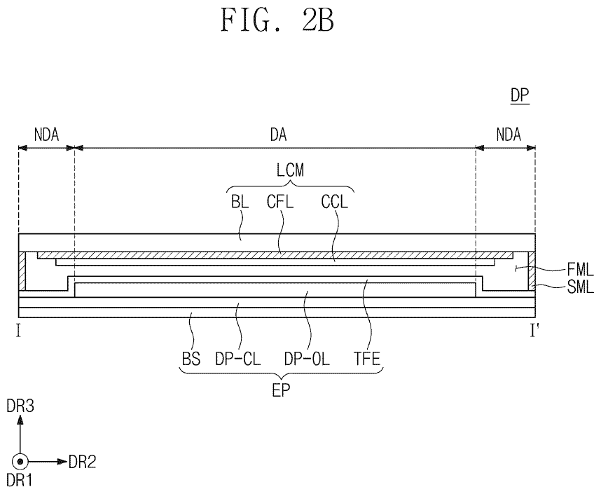

FIG. 1 is a perspective view of an electronic device of one or more embodiments. FIG. 2A is an exploded perspective view of an electronic device of one or more embodiments, and FIG. 2B is a cross-sectional view of a display panel according to one or more embodiments. FIG. 2B may be a cross-sectional view taken along the line I-I′ of FIG. 2A.

An electronic device DD may be activated in response to an electrical signal and be configured to display an image. The electronic device DD may include one or more suitable embodiments, and for example, the electronic device DD may include a small- and medium-sized device such as a monitor, a mobile phone, a tablet computer, a navigation device, and a game console as well as a large-sized device such as a television and an outdoor billboard. In one or more embodiments, embodiments of the electronic device DD are examples, and the electronic device DD is not limited to any one or more embodiments as long as the electronic device DD does not depart from the present disclosure.

In one or more embodiments, FIG. 1 and subsequent drawings illustrate a first direction axis DR1 to a third direction axis DR3, and directions indicated by first to third direction axes DR1, DR2, and DR3 described herein are relative concepts and may be changed into other directions. In addition, the directions indicated by the first to third direction axes DR1, DR2, and DR3 may be described as first to third directions and may be denoted as the same reference numerals or symbols.

In the present disclosure, a thickness direction of the electronic device DD may be a direction parallel to a third direction axis DR3 which is a normal direction with respect to a plane defined by a first direction axis DR1 and a second direction axis DR2. In the present disclosure, a front surface (or an upper surface) and a rear surface (or a lower surface) of members constituting the electronic device DD may be defined on the basis of the third direction axis DR3.

The electronic device DD may be configured to display an image IM in the third direction DR3 through a display surface IS parallel to a plane defined by the first direction DR1 and the second direction DR2. The third direction DR3 may be parallel to a normal direction of the display surface IS. The display surface IS on which the image IM is displayed may correspond to a front surface of the electronic device DD. The image IM may include a static image as well as a dynamic image. FIG. 1A illustrates icon images as an example of the image IM.

As used herein, the wording “in a plan view” may be defined as a state of being viewed in the third direction DR3. As used herein, the wording “in a cross-sectional view” may be defined as a state of being viewed in the first direction DR1 or the second direction DR2. In one or more embodiments, directions indicated by the first to third directions DR1, DR2, and DR3 are relative concepts and may be changed into other directions.

FIG. 1 illustrates the electronic device DD having the flat display surface IS. However, a shape of the display surface IS of the electronic device DD is not limited thereto, and the display surface IS may have a curved shape or a three-dimensional shape.

The electronic device DD may be flexible. The term “flexible” may imply bendable characteristic, and the electronic device DD may be a device including any one selected from among a structure which is completely foldable to a structure which is bendable to a level of several nanometers. For example, the flexible electronic device DD may include a curved electronic device or a foldable electronic device. However, one or more embodiments of the present disclosure is not limited thereto, and the electronic device DD may be rigid.

The display surface IS of the electronic device DD may include a display region D-DA and a peripheral region D-NDA. The image IM may be displayed in the display region D-DA. A user may view the image IM through the display region D-DA. In one or more embodiments illustrated in FIG. 1, and/or the like, the display region D-DA is illustrated as having a rectangular shape, but this is illustrated as an example, and the display region D-DA may have one or more suitable shapes.

The peripheral region D-NDA may be a non-display portion in which the image IM is not displayed. The peripheral region D-NDA may correspond to a portion that has a set or predetermined color and blocks light. The peripheral region D-NDA may be adjacent to the display region D-DA. For example, the peripheral region D-NDA may be arranged at an outer periphery of at least one side of the display region D-DA and be around (e.g., surround) the display region D-DA. However, this is illustrated as an example, and the peripheral region D-NDA may be adjacent to only one side of the display region D-DA or arranged on a side surface, not the front surface, of the electronic device DD. One or more embodiments of the present disclosure is not limited thereto, and the peripheral region D-NDA may not be provided.

In one or more embodiments, the electronic device DD of one or more embodiments may sense an external input applied from the outside. The external input may have one or more suitable forms such as pressure, temperature, light, and/or the like provided from the outside. The external input may include not only an input that makes contact (for example, a contact by a user's hand or a pen) with the electronic device DD but also an input (for example, hovering) applied close to the electronic device DD.

Referring to FIGS. 2A and 2B, an electronic device DD may include a window WM, a display panel DP, and a housing HAU, and the display panel DP may include a light-emitting panel EP and an optical structure layer LCM. The window WM and the housing HAU may be coupled to define an exterior of the electronic device DD and provide an internal space that is capable of accommodating components, such as the display panel DP, of the electronic device DD. For example, the display panel DP may be between the window WM and the housing HAU in the third direction DR3.

The window WM may be arranged on the display panel DP. The window WM may protect the display panel DP from an external impact. A front surface of the window WM may correspond to the display surface IS (see FIG. 1) of the electronic device DD described above. The front surface of the window WM may include a transmission region TA and a bezel region BA.

The transmission region TA of the window WM may be an optically transparent region. The window WM may be configured to transmit an image which is provided by the display panel DP through the transmission region TA, and a user may view the image. The transmission region TA may correspond to the display region D-DA (see FIG. 1) of the electronic device DD.

The window WM may include an optically transparent insulating material. For example, the window WM may include glass, sapphire, or plastic, but is not limited thereto. The window WM may have a single-layered or multi-layered structure. The window WM may further include functional layers such as a hard coating layer, a phase control layer, and an anti-fingerprint layer arranged on an optically transparent substrate.

The bezel region BA of the window WM may be provided as a region in which a material including a set or predetermined color is deposited, applied, or printed. The bezel region BA of the window WM may prevent or reduce viewing from the outside of a component of the display panel DP arranged to overlap the bezel region BA. The bezel region BA may correspond to the peripheral region D-NDA of the electronic device DD.

The display panel DP may display an image in response to an electrical signal. The display panel DP may include a display region DA and a non-display region NDA adjacent to the display region DA.

The display region DA may be a portion corresponding to the display region D-DA (see FIG. 1) of the electronic device DD. The display region DA may be a region which is activated in response to an electrical signal. The display region DA may be a region in which an image provided from the display panel DP is emitted. The display region DA of the display panel DP may correspond to the transmission region TA described above. In one or more embodiments, as used herein, the wording “a region/portion corresponds to a region/portion” refers to “a region/portion and a region/portion overlap each other” and is not limited to a case in which the regions/portions have the same area size and/or the same shape. An image that is displayed in the display region DA may be viewed from the outside through the transmission region TA.

The non-display region NDA may be adjacent to the display region DA. For example, the non-display region NDA may be around (e.g., surround) the display region DA. However, one or more embodiments of the present disclosure is not limited thereto, and the non-display region NDA may be defined in one or more suitable shapes. The non-display region NDA may be a portion corresponding to the peripheral region D-NDA (see FIG. 1) of the electronic device DD. The non-display region NDA may be a region in which a driving line or a driving circuit for driving the display region DA, one or more suitable types (kinds) of signal lines that provide an electrical signal, and pads are arranged. The non-display region NDA of the display panel DP may correspond to the bezel region BA described above. Components of the display panel DP arranged in the non-display region NDA may be prevented or reduced from being viewed from the outside by the bezel region BA. For example, the bezel region BA may prevent or reduce the viewing from the outside of the components of the display panel DP arranged in the non-display region NDA.

The light-emitting panel EP according to one or more embodiments may be an emissive display panel and is not limited thereto. For example, the light-emitting panel EP may be an organic light-emitting display panel, an inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include quantum dots, quantum rods, and/or the like. Hereinafter, the light-emitting panel EP will be described in more detail as an organic light-emitting display panel.

The light-emitting panel EP may include a base substrate BS, a circuit layer DP-CL, a display element layer DP-OL, and an encapsulation layer TFE. Each layer of the light-emitting panel EP will be described in more detail later.

The optical structure layer LCM may be arranged on the light-emitting panel EP. The optical structure layer LCM may be provided on the light-emitting panel EP and then coupled to the light-emitting panel EP through a bonding process using a sealing member SML.

However, one or more embodiments of the present disclosure is not limited thereto, and the optical structure layer LCM may be directly arranged on the light-emitting panel EP. In the present disclosure, forming through a continuous (e.g., substantially continuous) process without arranging a separate adhesive layer or adhesive member may be expressed as “directly arranged”. For example, the expression “the optical structure layer LCM is directly arranged on the light-emitting panel EP” may represent that a component of the optical structure layer LCM is formed through a continuous (e.g., substantially continuous) process on a base surface that is provided by the light-emitting panel EP after the light-emitting panel EP is formed.

The sealing member SML may be arranged in the non-display region NDA, which is an outer peripheral portion of the display panel DP, and prevent or reduce foreign substances, oxygen, moisture, and/or the like from being introduced into the display panel DP from the outside. The sealing member SML may be formed from sealant including a curable resin.

In addition, the display panel DP according to one or more embodiments may further include a filling layer FML arranged between the light-emitting panel EP and the optical structure layer LCM. The filling layer FML may fill a space between the light-emitting panel EP and the optical structure layer LCM. The filling layer FML may function as a buffer between the light-emitting panel EP and the optical structure layer LCM. In one or more embodiments, the filling layer FML may have an impact absorbing function, and/or the like, and increase the strength of the display panel DP. The filling layer FML may be formed from a filling resin including a polymer resin. For example, the filling layer FML may be formed from a filling layer resin including an acrylic resin, an epoxy-based resin, and/or the like. In one or more embodiments, the filling layer FML and the sealing member SML may not be provided, the optical structure layer LCM may be directly arranged on the light-emitting panel EP, and a base layer BL may not be provided in the optical structure layer LCM.

The optical structure layer LCM may include a light control layer CCL, a color filter layer CFL, and the base layer BL. Each layer of the optical structure layer LCM will be described in more detail later.

The housing HAU may be arranged under the display panel DP and accommodate the display panel DP. The housing HAU may protect the display panel DP by absorbing an impact applied from the outside and preventing or reducing foreign substances/moisture, and/or the like, from infiltrating the display panel DP. The housing HAU of one or more embodiments may be provided in a form in which a plurality of accommodation members are coupled to each other.

In one or more embodiments, the display panel DP may further include an input sensing unit. The input sensing unit may obtain coordinate information about an external input applied from the outside of the electronic device DD. The input sensing unit may be arranged between the light-emitting panel EP and the optical structure layer LCM. For example, the input sensing unit may be directly arranged on the light-emitting panel EP through a continuous (e.g., substantially continuous) process. One or more embodiments of the present disclosure are not limited thereto, and the input sensing unit may be manufactured separately and attached onto the light-emitting panel EP through an adhesive layer.

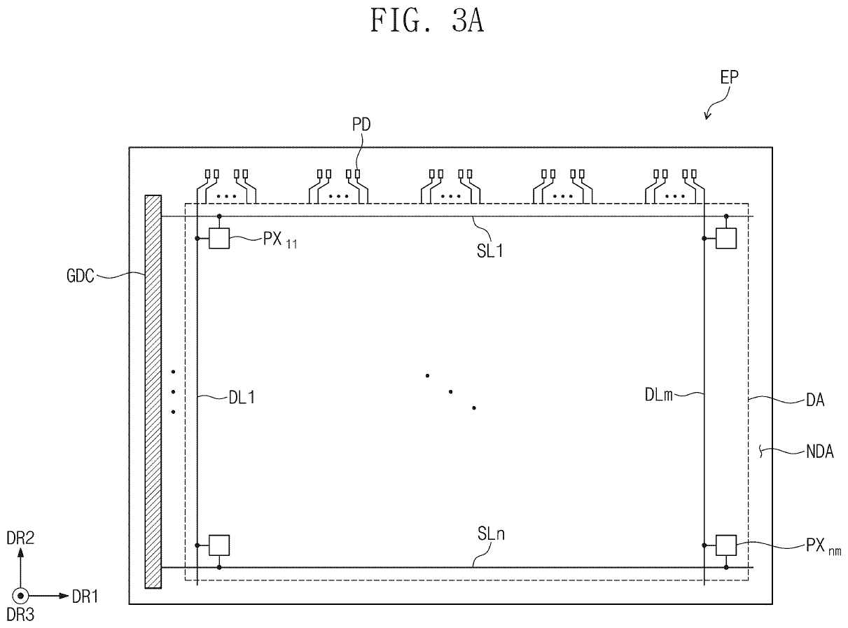

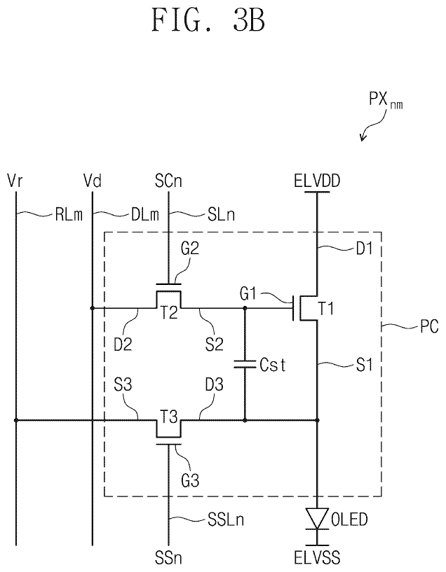

FIG. 3A is a plan view of a display panel according to one or more embodiments. FIG. 3B is an equivalent circuit diagram of a pixel according to one or more embodiments.

Referring to FIG. 3A, a light-emitting panel EP may include pixels PX₁₁ to PXₙₘ arranged in a display region DA and signal lines SL1 to SLn and DL1 to DLm electrically connected to the pixels PX₁₁ to PXₙₘ. The light-emitting panel EP may include a driving circuit GDC and pads PD which are arranged in a non-display region NDA. Here, m and n are natural numbers equal to or greater than 2.

The pixels PX₁₁ to PXₙₘ may each include a light-emitting element to be described in more detail later and a pixel driving circuit configured with a plurality of transistors (for example, a switching transistor, a driving transistor, and/or the like) connected to the light-emitting element and a capacitor. Each of the pixels PX₁₁ to PXₙₘ may be configured to emit light in response to an electrical signal applied to the pixel. FIG. 3A illustrates the pixels PX₁₁ to PXₙₘ arranged in a matrix form, but an arrangement form of the pixels PX₁₁ to PXₙₘ is not limited thereto.

The signal lines SL1 to SLn and DL1 to DLm may include scan lines SL1 to SLn and data lines DL1 to DLm. Each of the pixels PX₁₁ to PXₙₘ may be connected to a corresponding scan line among the scan lines SL1 to SLn and a corresponding data line among the data lines DL1 to DLm. More types (kinds) of signal lines may be provided in the light-emitting panel EP according to the configuration of a pixel driving circuit of the pixels PX₁₁ to PXₙₘ.

The driving circuit GDC may include a gate driving circuit. The gate driving circuit may generate gate signals and sequentially output the gate signals to the scan lines SL1 to SLn. The gate driving circuit may further output another control signal to the pixel driving circuit of the pixels PX₁₁ to PXₙₘ.

The pixels PX₁₁ to PXₙₘ and the driving circuit GDC according to one or more embodiments may include a plurality of thin-film transistors which are formed through a low temperature polycrystalline silicon (LTPS) process, a low temperature polycrystalline oxide (LTPO) process, or an oxide semiconductor process.

The pads PD may be arranged along one direction in the non-display region NDA. The pads PD may be a portion connected to a circuit board. Each of the pads PD may be connected to a corresponding signal line among the signal lines SL1 to SLn and DL1 to DLm and electrically connected to a corresponding pixel through the signal line. The pads PD may have an integrated shape with the signal lines SL1 to SLn and DL1 to DLm. However, one or more embodiments of the present disclosure is not limited thereto, and the pads PD may be arranged on a different layer from that of the signal lines SL1 to SLn and DL1 to DLm and may be connected to the signal lines SL1 to SLn and DL1 to DLm through a contact hole.

FIG. 3B illustrates a pixel PXₙₘ connected to an n-th scan line SLn, an n-th sensing line SSLn, an m-th data line DLm, and an m-th reference line RLm. Referring to FIG. 3B, the pixel PXₙₘ may include a pixel circuit PC and a light-emitting element OLED connected to the pixel circuit PC.

The pixel circuit PC may include a plurality of transistors T1, T2, and T3 and a capacitor Cst. The plurality of transistors T1, T2, and T3 may include a first transistor T1 (or a driving transistor), a second transistor T2 (or a switch transistor), and a third transistor T3 (a sensing transistor). Each of the first to third transistors T1, T2, and T3 may be a thin-film transistor.

The first to third transistors T1, T2, and T3 may be NMOS transistors, but are not limited thereto, and the first to third transistors T1, T2, and T3 may be PMOS transistors. The first to third transistors T1, T2, and T3 may respectively include sources S1, S2, and S3, drains D1, D2, and D3, and gates G1, G2, and G3.

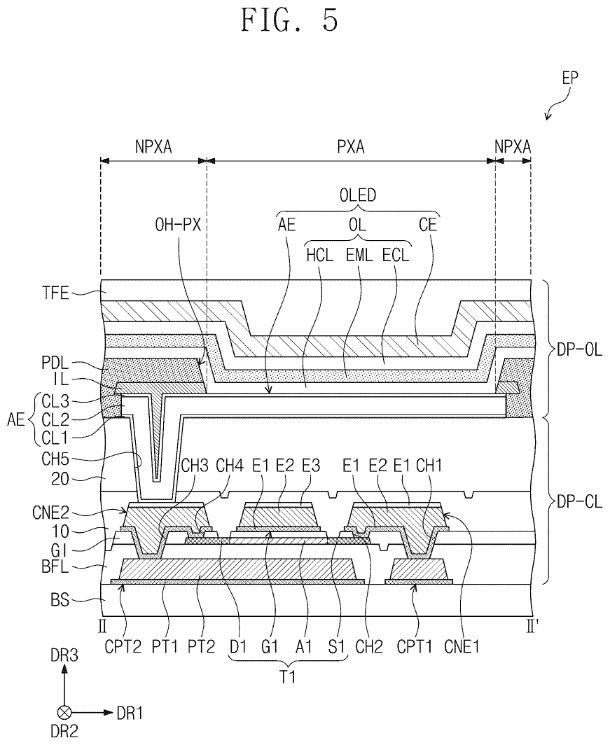

The light-emitting element OLED may be an organic light-emitting element including a first electrode AE (see FIG. 5) and a second electrode CE (see FIG. 5). In one or more embodiments, the first electrode AE (see FIG. 5) may be referred to as an anode or a pixel electrode, and the second electrode CE (see FIG. 5) may be referred to as a cathode or a common electrode. The first electrode AE (see FIG. 5) of the light-emitting element OLED may receive a first voltage ELVDD through the driving transistor T1, and the second electrode CE (see FIG. 5) of the light-emitting element OLED may receive a second voltage ELVSS. The light-emitting element OLED may receive the first voltage ELVDD and the second voltage ELVSS and may be configured to emit light.

The driving transistor T1 may include a drain D1 which receives the first voltage ELVDD, a source S1 which is connected to the first electrode AE (see FIG. 5) of the light-emitting element OLED, and a gate G1 which is connected to the capacitor Cst. The driving transistor T1 may control driving current which flows through the light-emitting element OLED from the first voltage ELVDD according to a voltage value stored in the capacitor Cst.

The switch transistor T2 may include a drain D2 which is connected to the m-th data line DLm, a source S2 which is connected to the capacitor Cst, and a gate G2 which receives an n-th write scan signal SCn. The m-th data line DLm may receive a data voltage Vd and a data voltage for sensing. The switch transistor T2 may transfer the data voltage Vd input from the m-th data line DLm to the driving transistor T1 according to a switching voltage input from the n-th write scan signal SCn.

The sensing transistor T3 may include a source S3 which is connected to the m-th reference line RLm, a drain D3 which is connected to the first electrode AE (see FIG. 5) of the light-emitting element OLED, and a gate G3 which receives an n-th sampling scan signal SSn. The m-th reference line RLm may receive a reference voltage Vr.

The capacitor Cst may be connected to the gate G1 of the driving transistor T1 and the first electrode AE (see FIG. 5) of the light-emitting element OLED. The capacitor Cst may include a first capacitor electrode connected to the gate G1 of the driving transistor T1 and a second capacitor electrode connected to the first electrode AE (see FIG. 5) of the light-emitting element OLED. The capacitor Cst may store a voltage corresponding to a difference between a voltage which is transmitted from the switch transistor T2 and the first voltage ELVDD.

In one or more embodiments, the equivalent circuit of the pixel PXₙₘ illustrated in FIG. 3B is represented as an example for one pixel PXₙₘ, and an equivalent circuit of the pixels PX₁₁ to PXₙₘ is not limited to that in FIG. 3B. In one or more embodiments of the present disclosure, an equivalent circuit diagram of the pixel PXₙₘ may be provided in one or more suitable forms so that the light-emitting element OLED is configured to emit light.

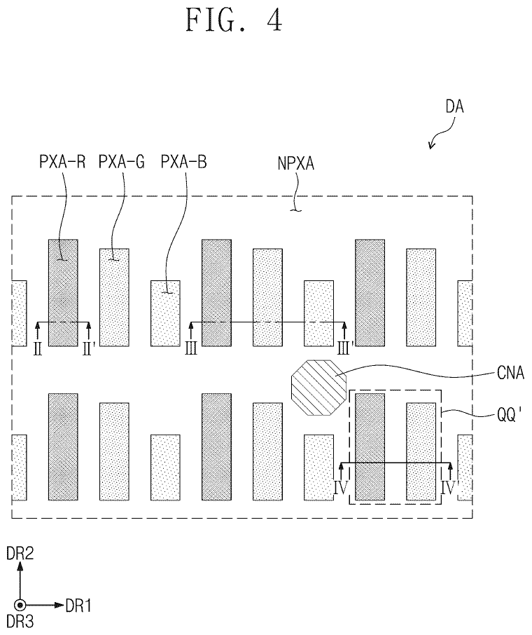

FIG. 4 is an enlarged plan view illustrating a portion of a display panel according to one or more embodiments.

FIG. 4 illustrates arrangement relationship of a plurality of pixel regions arranged in the display region DA in the display panel DP (see FIG. 3A) of one or more embodiments. In one or more embodiments of the present disclosure, a shape of pixel regions PXA-R, PXA-G, and PXA-B illustrated in FIG. 4 may be repeatedly arranged throughout the display region DA (see FIG. 3A).

Referring to FIG. 4, a peripheral region NPXA is arranged around first to third pixel regions PXA-R, PXA-G, and PXA-B. The peripheral region NPXA sets boundaries of the first to third pixel regions PXA-R, PXA-G, and PXA-B. The peripheral region NPXA may be around (e.g., surround) the first to third pixel regions PXA-R, PXA-G, and PXA-B.

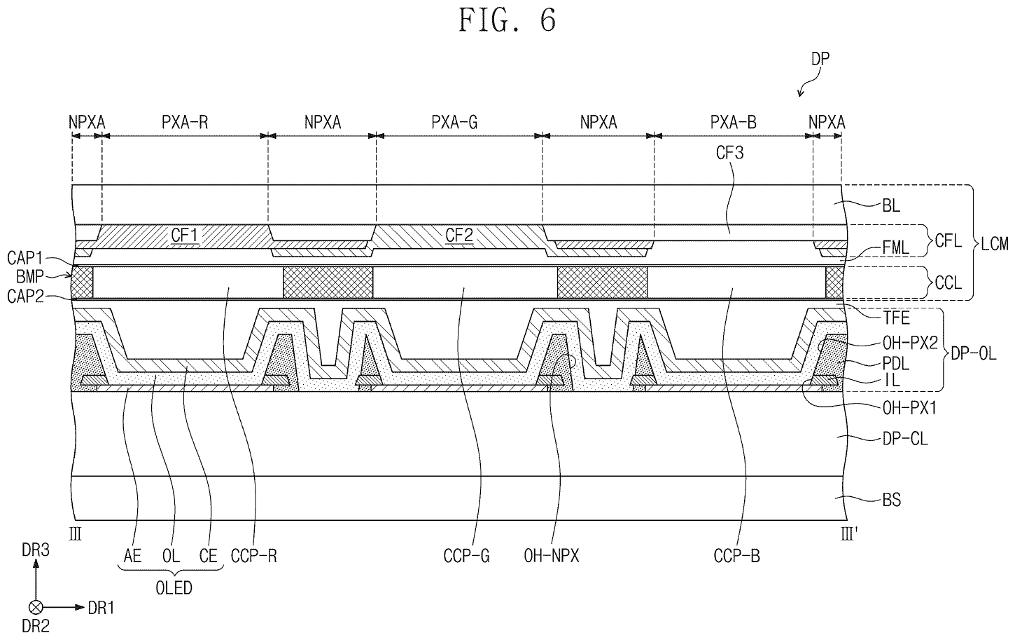

A structure, for example, a pixel-defining film PDL (see FIG. 6) or a bank BMP (see FIG. 6), which prevents or reduces color mixing between the first to third pixel regions PXA-R, PXA-G, and PXA-B may be arranged in the peripheral region NPXA. At least two color filters, among color filters CF1, CF2, and CF3 (see FIG. 6) to be described in more detail later, may be arranged to overlap in the peripheral region NPXA.

As illustrated in FIG. 4, each of the first to third pixel regions PXA-R, PXA-G, and PXA-B may have a rectangular shape. Each of the first to third pixel regions PXA-R, PXA-G, and PXA-B may have a rectangular shape having a short side extending along the first direction DR1 and a long side extending along the second direction DR2. An area size of the first to third pixel regions PXA-R, PXA-G, and PXA-B may be set according to a color of emitted light. A pixel region which is configured to emit light having a red color among primary colors may have the largest area size, and a pixel region which is configured to emit light having a blue color among primary colors may have the smallest area size. For example, the first pixel region PXA-R which is configured to emit red light may have the largest area size, and the third pixel region PXA-B which is configured to emit blue light may have the smallest area size.

FIG. 4 illustrates the first to third pixel regions PXA-R, PXA-G, and PXA-B having a rectangular shape, but one or more embodiments of the disclosure is not limited thereto. In a plan view, some of the first to third pixel regions PXA-R, PXA-G, and PXA-B may have a different polygonal shape (including a substantially polygonal shape). In one or more embodiments, the first to third pixel regions PXA-R, PXA-G, and PXA-B may have a rectangular shape (a substantially rectangular shape) having a round corner region in a plan view.

One of (e.g., selected from among) the first to third pixel regions PXA-R, PXA-G, and PXA-B may provide red light, another thereof may provide blue light, and the other thereof may provide green light. In one or more embodiments, the first pixel region PXA-R may provide red light, the second pixel region PXA-G may provide green light, and the third pixel-region PXA-B may provide blue light. In one or more embodiments, the first pixel region PXA-R may be configured to emit light having an emission wavelength of about 620 nm to about 700 nm, the second pixel region PXA-G may be configured to emit light having an emission wavelength of about 520 nm to about 600 nm, and the third pixel region PXA-B may be configured to emit light having an emission wavelength of about 410 nm to about 480 nm.

In one or more embodiments, a bank well region may be defined in the display region DA. The bank well region may be a region in which a bank well is formed so as to prevent or reduce defect caused by a dropping error in a process of printing some of a plurality of light control patterns CCP-R, CCP-G, and CCP-B (see FIG. 6) included in a light control layer CCL (see FIG. 6). For example, the bank well region may be a region in which the bank well that is formed by removing a portion of a bank BMP (see FIG. 6) is defined.

A connection region CNA may be defined in the peripheral region NPXA. The connection region CNA may overlap a bank BMP (see FIG. 6). The connection region CNA may be a region in which an auxiliary electrode and a second electrode CE are connected. The connection region CNA may be a portion in which the second electrode CE (see FIG. 5) is connected to the auxiliary electrode by removing a functional layer OL (see FIG. 5) included in a light-emitting element OLED (see FIG. 5) through a laser drilling process. An auxiliary electrode may include the same material as the first electrode AE (see FIG. 5) described above and may be formed on a circuit layer DP-CL (see FIG. 5) through the same (e.g., substantially the same) process as that for the first electrode AE (see FIG. 5) described above. The auxiliary electrode may be a conductive pattern to which a power voltage is applied. The auxiliary electrode may be a conductive pattern that provides the second voltage ELVSS (see FIG. 3B) to each of the pixels PXₙₘ (see FIG. 3A).

FIGS. 5 and 6 each are a cross-sectional view of a portion of a display panel according to one or more embodiments. FIG. 5 is a cross-sectional view, taken along the line II-II′ of FIG. 4, illustrating a portion corresponding to one pixel region PXA among pixel regions and the peripheral region NPXA adjacent thereto. FIG. 6 is a cross-sectional view, taken along the line III-III′ of FIG. 4, illustrating a portion corresponding to three pixel regions PXA-R, PXA-G, and PXA-B among the pixel regions and the peripheral region NPXA adjacent thereto.

Referring to FIGS. 5 and 6, a light-emitting panel EP according to one or more embodiments may include a base substrate BS, a circuit layer DP-CL, a display element layer DP-OL, and an encapsulation layer TFE which are sequentially stacked.

The light-emitting panel EP may include insulating layers, a semiconductor pattern, a conductive pattern, a signal line, and/or the like. In a process of manufacturing the light-emitting panel EP, an insulating layer, a semiconductor layer, and a conductive layer may be formed on the base substrate BS by coating, depositing, and/or the like. Thereafter, the insulating layer, the semiconductor layer, and the conductive layer may be patterned (e.g., selectively patterned) through photolithography. A semiconductor pattern, a conductive pattern, a signal line, and/or the like, included in the circuit layer DP-CL may be formed through such processes. Semiconductor patterns of the circuit layer DP-CL may be arranged across from the pixels in compliance with a set or predetermined rule.

The base substrate BS may include a glass substrate, a metal substrate, a polymer substrate, or an organic/inorganic composite material substrate. The base substrate BS may have a single-layered or multi-layered structure. For example, the base substrate BS having a multi-layered structure may include synthetic resin (e.g., organic) layers and at least one inorganic layer arranged between the synthetic resin layers. For example, the base substrate BS having a multi-layered structure may include synthetic resin layers and at least one organic layer arranged between the synthetic resin layers.

A synthetic resin layer of the base substrate BS may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, a perylene-based resin, or a polyimide-based resin. However, a material of the synthetic resin layer of the base substrate BS is not limited to the example.

The circuit layer DP-CL may be arranged on the base substrate BS. In the light-emitting panel EP according to one or more embodiments, the circuit layer DP-CL may include conductive patterns CPT1 and CPT2, a transistor T1, connection electrodes CNE1 and CNE2, a buffer layer BFL, and insulating layers GI, 10, and 20.

In one or more embodiments, FIG. 5 illustrates only one transistor T1 electrically connected to a light-emitting element OLED, but as illustrated in FIG. 3B, one pixel PXₙₘ may include a plurality of transistors for driving the light-emitting element OLED.

In one or more embodiments, the circuit layer DP-CL may include a first conductive pattern CPT1 and a second conductive pattern CPT2 arranged on the base substrate BS. In a plan view, the first conductive pattern CPT1 and the second conductive pattern CPT2 may be arranged to be spaced and/or apart (e.g., spaced apart or separated) from each other. The first conductive pattern CPT1 and the second conductive pattern CPT2 may be arranged below the transistor T1. The first conductive pattern CPT1 and the second conductive pattern CPT2 may have a stacked structure. The first conductive pattern CPT1 and the second conductive pattern CPT2 may each include a first pattern portion PT1 and a second pattern portion PT2 stacked in a thickness direction. In one or more embodiments, a thickness of the second pattern portion PT2 and a thickness of the first pattern portion PT1 may be different from each other. For example, in one or more embodiments, the thickness of the second pattern portion PT2 may be greater than the thickness of the first pattern portion PT1. However, one or more embodiments is not limited thereto.

Each of the first pattern portion PT1 and the second pattern portion PT2 may be formed of any one of molybdenum (Mo), aluminum (Al), chromium (Cr), gold (Au), titanium (Ti), nickel (Ni), neodymium (Nd), and copper (Cu) or alloy thereof. For example, the first pattern portion PT1 may include titanium (Ti), and the second pattern portion PT2 may include copper (Cu). However, one or more embodiments is not limited thereto.

The buffer layer BFL may be arranged on the first and second conductive patterns CPT1 and CPT2. The buffer layer BFL may be arranged on the base substrate BS so as to cover the first and second conductive patterns CPT1 and CPT2.

The buffer layer BFL may improve bonding force between the base substrate BS and a semiconductor pattern of the circuit layer DP-CL. The buffer layer BFL may include at least one of aluminum oxide, titanium oxide, silicon oxide, silicon nitride, silicon oxynitride, zirconium oxide, or hafnium oxide, and is not limited to these materials.

A semiconductor pattern of the circuit layer DP-CL may be arranged on the buffer layer BFL. The semiconductor pattern may include poly silicon. However, one or more embodiments of the disclosure is not limited thereto, and the semiconductor pattern may include amorphous silicon or metal oxide.

A source S1, an active A1, and a drain D1 of the transistor T1 may be formed from a semiconductor pattern. The semiconductor pattern of the transistor T1 may be divided into a plurality of regions according to a degree of conductivity (e.g., electrical conductivity). For example, the semiconductor pattern may have a different electrical property according to whether the semiconductor pattern is doped or not doped or whether metal oxide is reduced or not reduced. A region, of the semiconductor pattern, having relatively high conductivity (e.g., electrical conductivity) may serve as an electrode or a signal line and correspond to the source S1 or the drain D1 of the transistor T1. An undoped region, a region doped at a relatively low concentration, or a non-reduced region of the semiconductor pattern may have relatively low conductivity (e.g., electrical conductivity) and may correspond to the active A1 of the transistor T1.

The circuit layer DP-CL may include a plurality of transistors constituting the pixel circuit PC (see FIG. 3B) and a plurality of insulating layers. FIG. 5 illustrates the first transistor T1, an interlayer insulating layer GI, a first insulating layer 10, and a second insulating layer 20. The interlayer insulating layer GI, the first insulating layer 10, and the second insulating layer 20 may be sequentially arranged on the buffer layer BFL. The insulating layers GI, 10, and 20 may include an inorganic layer or an organic layer and may have a single-layered structure or a multi-layered structure.

The inorganic layer may include at least one of aluminum oxide, titanium oxide, silicon oxide, silicon nitride, silicon oxynitride, zirconium oxide, or hafnium oxide, but is not limited to these materials. The organic layer may include a phenol-based polymer, an acrylic polymer, an imide-based polymer, an aryl ether-based polymer, an amide-based polymer, a fluorine-based polymer, a p-xylene-based polymer, a vinyl alcohol-based polymer, and/or a (e.g., any suitable) combination thereof, but is not limited to the materials.

The interlayer insulating layer GI may cover the semiconductor pattern of the circuit layer DP-CL. A gate G1 of the first transistor T1 may be arranged on the interlayer insulating layer GI. The gate G1 may be a portion of a conductive pattern. The gate G1 may overlap the active A1. The gate G1 may function as a mask in a process of doping the semiconductor pattern. The interlayer insulating layer GI may be an inorganic layer.

The first insulating layer 10 may be arranged on the interlayer insulating layer GI and cover the gate G1. The second insulating layer 20 may be arranged on the first insulating layer 10. For example, the second insulating layer 20 may overlap the first insulating layer 10 in the third direction DR3.

In one or more embodiments, a layer including a transistor (for example, the first transistor T1 of FIG. 5) which is formed among the buffer layer BFL, the interlayer insulating layer GI, the first insulating layer 10, and the second insulating layer 20 may be defined as a transistor layer.

The gate G1 and the connection electrodes CNE1 and CNE2 may be arranged on the interlayer insulating layer GI. The gate G1, a first connection electrode CNE1, and a second connection electrode CNE2 may be arranged to be spaced and/or apart (e.g., spaced apart or separated) from each other on the interlayer insulating layer GI. The gate G1, the first connection electrode CNE1, and the second connection electrode CNE2 may be formed by being concurrently (e.g., simultaneously) patterned with the same material. The gate G1, the first connection electrode CNE1, and the second connection electrode CNE2 may each have a structure in which a plurality of layers are stacked. For example, the gate G1, the first connection electrode CNE1, and the second connection electrode CNE2 may each include a first sub layer E1, a second sub layer E2, and a third sub layer E3 which are sequentially stacked. However, one or more embodiments is not limited thereto, and the gate G1, the first connection electrode CNE1, and the second connection electrode CNE2 may each have a structure in which two layers are stacked or at least four layers are stacked.

Each of the gate G1, the first connection electrode CNE1, and the second connection electrode CNE2 may include (e.g., may be formed of) a metal material. Each of the gate G1, the first connection electrode CNE1, and the second connection electrode CNE2 may include (e.g., may be formed of) any one of molybdenum (Mo), aluminum (Al), chromium (Cr), gold (Au), titanium (Ti), nickel (Ni), neodymium (Nd), or copper (Cu), and/or indium tin oxide (ITO), and/or an alloy selected from among molybdenum (Mo), aluminum (Al), chromium (Cr), gold (Au), titanium (Ti), nickel (Ni), neodymium (Nd), and copper (Cu). For example, the first sub layer E1 may include titanium (Ti), the second sub layer E2 may include copper (Cu), and the third sub layer E3 may include ITO. However, one or more embodiments is not limited thereto.

The first connection electrode CNE1 may be connected to the first conductive pattern CPT1 through a first contact hole CH1 defined in the interlayer insulating layer GI and the buffer layer BFL. The first connection electrode CNE1 may be connected to the source S1 through a second contact hole CH2 defined in the interlayer insulating layer GI. In one or more embodiments, the first connection electrode CNE1 may be connected to a power line which is configured to supply the power to be provided to the light-emitting element OLED. A first voltage may be provided to the transistor T1 through the power line.

The second connection electrode CNE2 may be connected to the second conductive pattern CPT2 through a third contact hole CH3 defined in the interlayer insulating layer GI and the buffer layer BFL. The second connection electrode CNE2 may be connected to the drain D1 through a fourth contact hole CH4 defined in the interlayer insulating layer GI. The drain D1, which is a semiconductor pattern, itself may not have high current transmission characteristics. In a case in which the second conductive pattern CPT2 including metal is connected to the drain D1, characteristics of current transmission through the drain D1 may be improved.

The first insulating layer 10 may be arranged on the gate G1, the first connection electrode CNE1, and the second connection electrode CNE2. The first insulating layer 10 may include an inorganic layer. For example, the first insulating layer 10 may include silicon oxide. The first insulating layer 10 may be arranged on the buffer layer BFL so as to cover the gate G1, the first connection electrode CNE1, and the second connection electrode CNE2.

The second insulating layer 20 may be arranged on the first insulating layer 10. The second insulating layer 20 may include an organic layer. The second insulating layer 20 may provide a flat upper surface. However, one or more embodiments is not limited thereto.

The display element layer DP-OL including the light-emitting element OLED and a pixel-defining film PDL may be arranged on the circuit layer DP-CL. In addition, the display element layer DP-OL may include the encapsulation layer TFE arranged on the light-emitting element OLED. FIGS. 5 and 6 illustrate one pixel region PXA or three pixel regions PXA-R, PXA-G, and PXA-B and the peripheral region NPXA adjacent thereto, but a stacked structure of the pixel region PXA and the peripheral region NPXA illustrated in FIGS. 5 and 6, and/or the like, may be equally applied to other portions.

In an electronic device according to one or more embodiments, the light-emitting element OLED may include a first electrode AE, a functional layer OL, and a second electrode CE which are sequentially stacked. The functional layer OL may include a hole transport region HCL, an emission layer EML, and an electron transport region ECL.

The first electrode AE of the light-emitting element OLED may be arranged on the second insulating layer 20. The first electrode AE may be connected to the second connection electrode CNE2 through a fifth contact hole CH5 defined in the second insulating layer 20 and the first insulating layer 10. Because the first electrode AE is connected to the second connection electrode CNE2, the drain D1 may be connected to the light-emitting element OLED through the second connection electrode CNE2. In addition, the second connection electrode CNE2 may be connected to the light-emitting element OLED through the first electrode AE.

The first electrode AE may include (e.g., may be formed of) a metal material, metal alloy, or conductive compound. The first electrode AE may be a transmissive electrode, semi-transmissive electrode, or reflective electrode. The first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture (for example, a mixture of Ag and Mg) thereof. In one or more embodiments, the first electrode AE may have a multi-layered structure including a reflective or semi-transmissive film which includes (e.g., is formed of) the above material and a transparent conductive film which includes (e.g., is formed of) indium tin oxide (ITO), indium zinc oxide (IZO), zinc oxide (ZnO), indium tin zinc oxide (ITZO), and/or the like. For example, the first electrode AE may include a first layer CL1, a second layer CL2, and a third layer CL3 which are sequentially stacked. For example, the first electrode AE may have a triple-layered structure including ITO in the first layer CL1, Ag in the second layer CL2, and ITO in the third layer CL3, but one or more embodiments are not limited thereto.

The hole transport region HCL is provided on the first electrode AE. The hole transport region HCL may have a single-layered structure including a single material, a single-layered structure including a plurality of different materials, or a multi-layered structure having a plurality of layers including a plurality of different materials. For example, the multi-layered structure may include a plurality of different materials in each layer of the plurality of layers or may include a single material in each layer of the plurality of layers, the single material in each layer being different from each other.

The hole transport region HCL may include at least one of a hole injection layer, a hole transport layer, or an electron blocking layer. In addition, the hole transport region HCL may include a plurality of hole transport layers which are stacked.

The emission layer EML may be arranged on the hole transport region HCL. The emission layer EML may have a single-layered structure including a single material, a single-layered structure including a plurality of different materials, or a multi-layered structure having a plurality of layers including a plurality of different materials. In one or more embodiments, the emission layer EML may be configured to emit blue light that is source light. However, one or more embodiments is not limited thereto, and the display element layer DP-OL may include light-emitting elements OLED including emission layers EML that are configured to emit light of different wavelength regions.

The electron transport region ECL may be arranged on the emission layer EML. The electron transport region ECL may have a single-layered structure including a single material, a single-layered structure including a plurality of different materials, or a multi-layered structure having a plurality of layers including a plurality of different materials. For example, the multi-layered structure may include a plurality of different materials in each layer of the plurality of layers or may include a single material in each layer of the plurality of layers, the single material in each layer being different from each other. The electron transport region ECL may include at least one of a hole blocking layer, an electron transport layer, or an electron injection layer, but one or more embodiments is not limited thereto.

The hole transport region HCL, the emission layer EML, the electron transport region ECL, and/or the like may be each formed by using one or more suitable methods such as a vacuum deposition method, a spin coating method, a casting method, a Langmuir-Blodgett (LB) method, an inkjet printing method, a laser printing method, and a laser induced thermal imaging (LITI) method.

In one or more embodiments, in the light-emitting element OLED of one or more embodiments illustrated in FIGS. 5 and 6, the hole transport region HCL, the emission layer EML, the electron transport region ECL, and/or the like may be provided as a common layer so as to overlap all of a plurality of pixel regions PXA and the peripheral region NPXA. However, one or more embodiments is not limited thereto, and the emission layer EML may be provided by being patterned so as to correspond to only a portion of the peripheral region NPXA adjacent to the pixel region PXA and the pixel region PXA.

The second electrode CE is provided on the electron transport region ECL. The second electrode CE may be a common electrode. For example, in the light-emitting element OLED of one or more embodiments, the second electrode CE may be provided as a common layer so as to overlap all of the plurality of pixel regions PXA and the peripheral region NPXA.

The second electrode CE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, or a compound or mixture (for example, AgMg, AgYb, or MgYb) including the same. In one or more embodiments, the second electrode CE may have a multi-layered structure including a reflective or semi-transmissive film which includes (e.g., is formed of) the above material and a transparent conductive film which is formed of indium tin oxide (ITO), indium zinc oxide (IZO), zinc oxide (ZnO), indium tin zinc oxide (ITZO), and/or the like. For example, the second electrode CE may include the metal material described above, a combination of two or more metal materials selected from among the metal materials described above, an oxide of the metal materials described above, and/or the like.

The display element layer DP-OL includes the pixel-defining film PDL and an inorganic layer IL arranged on the circuit layer DP-CL. The inorganic layer IL may be arranged on the first electrode AE. A first pixel opening OH-PX1 may be defined in the inorganic layer IL in correspondence to the pixel region PXA. A portion of the first electrode AE may be exposed in the first pixel opening OH-PX1. In one or more embodiments, the pixel region PXA may correspond to the exposed portion of the first electrode AE.

The inorganic layer IL may include an inorganic material. The inorganic layer IL may include an insulating material including silicon. The inorganic layer IL may include silicon nitride (SiNₓ), silicon oxide (SiOₓ), silicon oxynitride (SiOₓN_{y}), and/or the like. For example, the inorganic layer IL may include silicon nitride (SiNₓ), but a material of the inorganic layer IL is not limited to the example.

The display element layer DP-OL includes the pixel-defining film PDL arranged on the circuit layer DP-CL. The pixel-defining film PDL may be arranged on the second insulating layer 20. A second pixel opening OH-PX2 may be defined in the pixel-defining film PDL in correspondence to the pixel region PXA. The second pixel opening OH-PX2 may be defined on the first pixel opening OH-PX1 in correspondence to the first pixel opening OH-PX1. In addition, a peripheral opening OH-NPX may be defined in the pixel-defining film PDL to overlap the peripheral region NPXA.

At least a portion of the pixel-defining film PDL is arranged on the inorganic layer IL. The second pixel opening OH-PX2 of the pixel-defining film PDL may be defined on the first pixel opening OH-PX1 of a corresponding inorganic layer IL. The pixel-defining film PDL may cover at least a portion of an upper surface of the inorganic layer IL.

The pixel-defining film PDL may include a light-absorbing material or have a set or predetermined color. For example, the pixel-defining film PDL may include a base resin and black dye and/or a black pigment mixed in the base resin. The pixel-defining film PDL may include an organic material. For example, the pixel-defining film PDL may include a polyacrylate-based resin or a polyimide-based resin, but a material of the pixel-defining film PDL is not limited to the example. The inorganic layer IL and the pixel-defining film PDL will be described in more detail later.

The encapsulation layer TFE may cover the light-emitting element OLED. The encapsulation layer TFE may encapsulate the light-emitting element OLED. The encapsulation layer TFE may be a thin-film encapsulation layer. The encapsulation layer TFE may be one layer or a plurality of layers that are stacked. The encapsulation layer TFE includes at least one insulating layer. The encapsulation layer TFE according to one or more embodiments may include at least one inorganic film (hereinafter, an inorganic encapsulation film). In addition, the encapsulation layer TFE according to one or more embodiments may include at least one organic film (hereinafter, an organic encapsulation film) and at least one inorganic encapsulation film.

The inorganic encapsulation film protects the light-emitting element OLED from moisture/oxygen, and the organic encapsulation film protects the light-emitting element OLED from foreign substances such as dust particles. The inorganic encapsulation film may include silicon nitride, silicon oxynitride, silicon oxide, titanium oxide, aluminum oxide, and/or the like and is not particularly limited thereto. The organic encapsulation film may include an acrylic compound, an epoxy-based compound, and/or the like. The organic encapsulation film may include a photopolymerizable organic material and is not particularly limited.

An optical structure layer LCM may be arranged on the display element layer DP-OL. The optical structure layer LCM may include a light control layer CCL, a color filter layer CFL, and a base layer BL.

The light control layer CCL may include a light converter. The light converter may be a quantum dot, a phosphor, and/or the like. The light converter may be configured to convert a wavelength of provided light and be configured to emit the light. For example, the light control layer CCL may be a layer of which at least a portion includes a quantum dot or a phosphor.

The light control layer CCL may include a plurality of light control patterns CCP-R, CCP-G, and CCP-B. The light control patterns CCP-R, CCP-G, and CCP-B may be spaced and/or apart (e.g., spaced apart or separated) from each other. The light control patterns CCP-R, CCP-G, and CCP-B may be arranged to be spaced and/or apart (e.g., spaced apart or separated) from each other by a bank BMP. The light control patterns CCP-R, CCP-G, and CCP-B may be arranged in a bank opening defined in the bank BMP. However, one or more embodiments is not limited thereto. FIG. 6 illustrates that, in a cross-sectional view, the bank BMP has a rectangular shape and does not overlap the light control patterns CCP-R, CCP-G, and CCP-B, but an edge of a portion of the light control patterns CCP-R, CCP-G, and CCP-B may at least partially overlap the bank BMP. For example, an edge of a third light control pattern CCP-B may be arranged so as to overlap the bank BMP in a plan view. The bank BMP may have a trapezoidal shape in a cross-sectional view. The bank BMP may have a shape of which a cross-sectional width increases toward the display element layer DP-OL.

The light control patterns CCP-R, CCP-G, and CCP-B may be a portion which is configured to convert a wavelength of light that is provided from the display element layer DP-OL or configured to transmit the provided light.

The light control layer CCL may include a first light control pattern CCP-R which provides red light that is first light, a second light control pattern CCP-G which provides green light that is second light, and the third light control pattern CCP-B which provides blue light that is third light. The light control layer CCL may include the first light control pattern CCP-R which converts source light provided from the light-emitting element OLED into the first light, the second light control pattern CCP-G which converts the source light into the second light, and the third light control pattern CCP-B which is configured to transmit the source light. At least a portion of the light control patterns CCP-R, CCP-G, and CCP-B may include a quantum dot which converts the source light into light having a specific wavelength.

The light control layer CCL may further include a scatterer. The first light control pattern CCP-R may include a first quantum dot and a scatterer, the second light control pattern CCP-G may include a second quantum dot and a scatterer, and the third light control pattern CCP-B may not include (e.g., may exclude) a quantum dot and may include a scatterer. The first light control pattern CCP-R, the second light control pattern CCP-G, and the third light control pattern CCP-B may each further include a base resin which disperses a quantum dot and a scatterer.

The light control layer CCL may include a first barrier layer CAP1 arranged on one surface of the first light control pattern CCP-R. The light control layer CCL may include the first barrier layer CAP1 spaced and/or apart (e.g., spaced apart or separated) from the display element layer DP-OL with the first light control pattern CCP-R therebetween and a second barrier layer CAP2 adjacent to the display element layer DP-OL.

In a display panel DP, the optical structure layer LCM includes the color filter layer CFL arranged on the light control layer CCL. The color filter layer CFL may include color filters CF1, CF2, and CF3. The color filter layer CFL may include a first color filer CF1 which is configured to transmit a first light, a second color filter CF2 which is configured to transmit a second light, and a third color filter CF3 which is configured to transmit a source light. In one or more embodiments, the first color filter CF1 may be a red filter, the second color filter CF2 may be a green filter, and the third color filter CF3 may be a blue filter.

The color filters CF1, CF2, and CF3 each include a polymer photosensitive resin and a colorant. The first color filter CF1 may include a red colorant, the second color filter CF2 may include a green colorant, and the third color filter CF3 may include a blue colorant. The first color filter CF1 may include a red pigment or red dye, the second color filter CF2 may include a green pigment or green dye, and the third color filter CF3 may include a blue pigment or blue dye.

The first to third color filters CF1, CF2, and CF3 may be arranged in correspondence to a first pixel region PXA-R, a second pixel region PXA-G, and a third pixel region PXA-B, respectively. In addition, the first to third color filters CF1, CF2, and CF3 may be arranged in correspondence to the first to third light control patterns CCP-R, CCP-G, and CCP-B, respectively.

In addition, the plurality of color filters CF1, CF2, and CF3 that transmit different light may be arranged to overlap in correspondence to the peripheral region NPXA arranged between the pixel regions PXA-R, PXA-G, and PXA-B. The plurality of color filters CF1, CF2, and CF3 may be arranged to overlap in a third direction DR3, which is a thickness direction, to define boundaries between adjacent pixel regions PXA-R, PXA-G, and PXA-B. For example, the plurality of color filters CF1, CF2, and CF3 may overlap each other in the third direction DR3 (e.g., the thickness direction) in the peripheral region NPXA. In one or more embodiments, unlike the illustration, the color filter layer CFL may include a light blocking portion to define boundaries between adjacent color filters CF1, CF2, and CF3. The light blocking portion may be formed of a blue filter or may be formed including an inorganic light blocking material or an organic light blocking material containing a black pigment or black dye.

The optical structure layer LCM may include a filling layer FML arranged between the light control layer CCL and the color filter layer CFL. The filling layer FML may be arranged between the light control patterns CCP-R, CCP-G, and CCP-B and the color filters CF1, CF2, and CF3. The filling layer FML may be arranged above the light control layer CCL and prevent or reduce the light control patterns CCP-R, CCP-G, and CCP-B from being exposed to moisture/oxygen. In addition, the filling layer FML may be arranged between the light control patterns CCP-R, CCP-G, and CCP-B and the color filters CF1, CF2, and CF3 and function as an optical function layer which, for example, increases light extraction efficiency or prevents or reduces reflected light from being incident to the light control layer CCL. The filling layer FML may be a layer having a lower refractive index compared to other layers adjacent thereto.

In one or more embodiments, the optical structure layer LCM may further include the base layer BL arranged on the color filter layer CFL. The base layer BL may be a member that provides a base surface on which the color filter layer CFL, the light control layer CCL, and/or the like are arranged. The base layer BL may be a glass substrate, a metal substrate, a plastic substrate, and/or the like. However, one or more embodiments is not limited thereto, and the base layer BL may be an inorganic layer, an organic layer, or a composite material layer. In addition, unlike the illustration, in one or more embodiments, the base layer BL may not be provided.

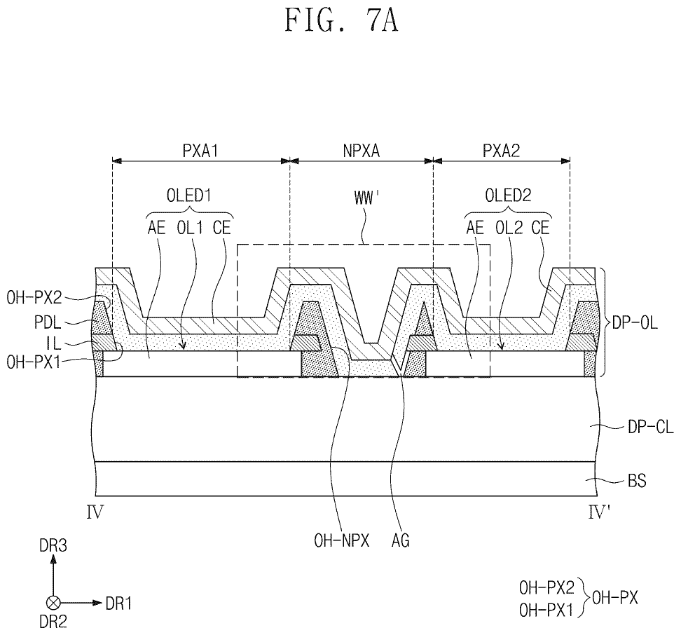

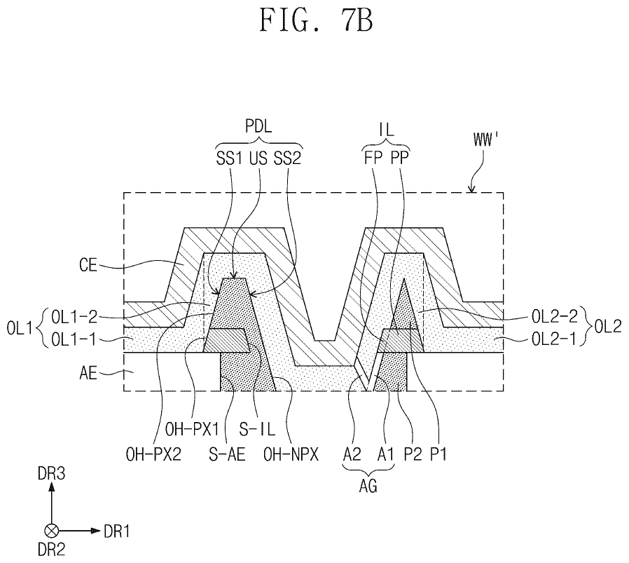

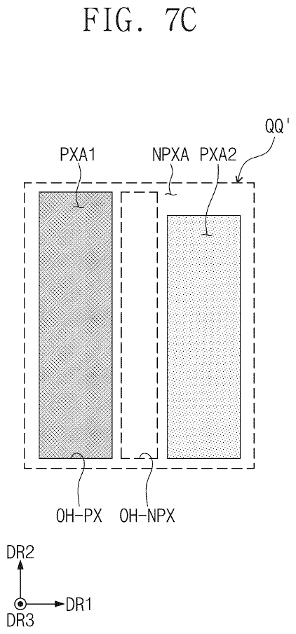

FIG. 7A is a cross-sectional view illustrating a portion of a display panel according to one or more embodiments in more detail. FIG. 7B is an enlarged cross-sectional view of a portion of a display panel according to one or more embodiments. FIG. 7C is an enlarged plan view of a portion of a display panel according to one or more embodiments. FIG. 8 is an enlarged cross-sectional view of a portion of a display panel according to one or more embodiments. FIGS. 7A to 7C and 8 are illustrated for more detailed description of display element layers DP-OL and DP-OLa according to one or more embodiments of the disclosure. FIG. 7A is a cross-sectional view, taken along the line IV-IV′ of FIG. 4, illustrating a portion corresponding to two pixel regions PXA-R and PXA-G among the pixel regions and the peripheral region NPXA adjacent thereto. FIG. 7B illustrates enlarged region WW of FIG. 7A in more detail, and FIG. 8 illustrates an enlarged cross section of a display panel of one or more embodiments corresponding thereto. FIG. 7C illustrates enlarged region QQ′ of FIG. 4 in more detail. However, descriptions to be made later with reference to FIGS. 7A to 7C and 8 are not limited to the first and second pixel regions PXA-R and PXA-G described above and may describe any two pixel regions PXA1 and PXA2, selected from among the pixel regions PXA-R, PXA-G, and PXA-B, adjacent to each other.

Referring to FIGS. 7A to 7C, the display element layer DP-OL according to one or more embodiments may include first and second light-emitting elements OLED1 and OLED2, the pixel-defining film PDL, and the inorganic layer IL. The first and second light-emitting elements OLED1 and OLED2 may respectively include first and second functional layers OL1 and OL2. The first and second functional layers OL1 and OL2 may be arranged in pixel openings OH-PX1 and OH-PX2, and the pixel openings OH-PX1 and OH-PX2 may be defined in the inorganic layer IL and the pixel-defining film PDL.

The inorganic layer IL may be arranged on a first electrode AE. A first pixel opening OH-PX1 may be defined in the inorganic layer IL in correspondence to the pixel regions PXA1 and PXA2. The first pixel opening OH-PX1 may overlap the pixel regions PXA1 and PXA2, and the inorganic layer IL may overlap the peripheral region NPXA. A portion of the first electrode AE may be exposed in the first pixel opening OH-PX1. The pixel regions PXA1 and PXA2 may correspond to the exposed portion of the first electrode AE. The functional layers OL1 and OL2 may be arranged in the first pixel opening OH-PX1.

A side surface S-IL of the inorganic layer IL may not be continuous (e.g., may not be substantially continuous) with a side surface S-AE of the first electrode AE corresponding thereto, and the side surface S-IL of the inorganic layer IL and the side surface S-AE of the first electrode AE may form a step. The inorganic layer IL may have a shape extending further in a direction away from the pixel regions PXA1 and PXA2 compared to the first electrode AE. Accordingly, the display element layer DP-OL according to one or more embodiments of the disclosure may have an undercut shape under the inorganic layer IL. In one or more embodiments, in the present disclosure, the side surface S-IL of the inorganic layer IL may refer to a side surface, among side surfaces extending from an upper surface of the inorganic layer IL, not defining the first pixel opening OH-PX1 and being further adjacent to the peripheral region NPXA. For example, the side surface S-IL of the inorganic layer IL may refer to another surface opposed to one surface, of the inorganic layer IL, defining the first pixel opening OH-PX1.

The pixel-defining film PDL may be arranged on the circuit layer DP-CL. At least a portion of the pixel-defining film PDL is arranged on the inorganic layer IL. At least a portion of the pixel-defining film PDL may cover the inorganic layer IL. A lower space of an undercut formed due to a step that is formed by the side surface S-IL of the inorganic layer IL and the side surface S-AE of the first electrode AE may be filled with the pixel-defining film PDL.

The pixel-defining film PDL may include an upper surface US, and a first side surface SS1 and a second side surface SS2 each extending from the upper surface US and opposite to each other.

A second pixel opening OH-PX2 is defined in the pixel-defining film PDL in correspondence to the pixel regions PXA1 and PXA2. The second pixel opening OH-PX2 may be defined by the first side surface SS1 and defined on the first pixel opening OH-PX1 in correspondence to the first pixel opening OH-PX1. The functional layers OL1 and OL2 may be arranged in the second pixel opening OH-PX2.

A peripheral opening OH-NPX is defined in the pixel-defining film PDL to overlap the peripheral region NPXA. The peripheral opening OH-NPX may be defined by the second side surface SS2. A portion of an upper surface of the circuit layer DP-CL may be exposed in the peripheral opening OH-NPX. A portion of an upper surface of the second insulating layer 20 (see FIG. 5) may be exposed in the peripheral opening OH-NPX. The functional layers OL1 and OL2 may be arranged not only in the first and second pixel openings OH-PX1 and OH-PX2 but also in the peripheral opening OH-NPX. However, because the functional layers OL1 and OL2 arranged in the peripheral opening OH-NPX are in contact not with the first electrode AE but with the upper surface of the circuit layer DP-CL, the light-emitting elements OLED1 and OLED2 may not be configured to emit light in the peripheral region NPXA.

At least a portion of the side surface S-IL of the inorganic layer IL may be exposed in the peripheral opening OH-NPX. Accordingly, at least a portion of the inorganic layer IL has a shape protruding from the second side surface SS2 of the pixel-defining film PDL to an inner side of the peripheral opening OH-NPX.

FIG. 7A illustrates that, in the peripheral region NPXA arranged between two pixel regions PXA1 and PXA2, the side surface S-IL of the inorganic layer IL arranged on the first electrode AE of a first pixel region PXA1 is not exposed by the peripheral opening OH-NPX and the side surface S-IL of the inorganic layer IL arranged on the first electrode AE of a second pixel region PXA2 is exposed by the peripheral opening OH-NPX, but one or more embodiments is not limited thereto. For example, unlike the illustration, the side surface S-IL of the inorganic layer IL arranged on the first electrode AE of the first pixel region PXA1 and the side surface S-IL of the inorganic layer IL arranged on the first electrode AE of the second pixel region PXA2 both (e.g., simultaneously) may be exposed by the peripheral opening OH-NPX. FIG. 7C illustrates that a shape of the peripheral opening OH-NPX in a plan view is a rectangle, but one or more embodiments of the present disclosure is not limited thereto, and the peripheral opening OH-NPX may have a different polygonal shape (including a substantially polygonal shape) in a plan view. In addition, the peripheral opening OH-NPX may be defined to be biased to any one pixel region PXA1 or PXA2 between the two pixel regions PXA1 and PXA2, or may be defined in a central region between the two pixel regions PXA1 and PXA2. In one or more embodiments, as to be described in more detail later, the peripheral opening OH-NPX may have one or more suitable structures if necessary or desired without limitation as long as the functional layers OL1 and OL2 may be disconnected in the peripheral region NPXA by an air gap AG which is defined in the peripheral opening OH-NPX.

The pixel-defining film PDL may include a first portion P1 and a second portion P2. The first portion P1 and the second portion P2 may be spaced and/or apart (e.g., spaced apart or separated) with the inorganic layer IL therebetween in a cross-sectional view. The first portion P1 may be directly arranged on the inorganic layer IL, and the second portion P2 may be directly arranged on the circuit layer DP-CL. The second portion P2 may be arranged on the same layer as the first electrode AE. For example, both the second portion P2 and the first electrode A may be situated at the same level and/or the second portion P2 may overlap the first electrode AE in the first direction DR1. In one or more embodiments, the inorganic layer IL may have a shape penetrating the pixel-defining film PDL. The inorganic layer IL may include a protruding portion FP and a flat portion PP. The protruding portion FP may refer to a portion protruding from the second side surface SS2 of the pixel-defining film PDL toward an inner side of the peripheral opening OH-NPX. The flat portion PP may refer to a portion arranged between the first portion P1 and the second portion P2.

The air gap AG may include a first space A1 and a second space A2. The side surface S-IL of the inorganic layer IL may not be continuous (e.g., substantially continuous) with the second side surface SS2 of the pixel-defining film PDL corresponding thereto, and the side surface S-IL of the inorganic layer IL and the second surface SS2 of the pixel-defining film PDL may form a step. Accordingly, the display element layer DP-OL according to one or more embodiments of the present disclosure may have an undercut shape under the protruding portion FP, and the first space A1 may be defined in the peripheral opening OH-NPX. The first space A1 may refer to an air gap which is defined below an undercut between the protruding portion FP and the second portion P2 of the pixel-defining film PDL. The second portion P2 of the pixel-defining film PDL may be spaced and/or apart (e.g., spaced apart or separated) from the functional layers OL1 and OL2 with the first space A1 therebetween.

At least a portion of the functional layers OL1 and OL2 may have a shape cut in the peripheral region NPXA by the air gap AG. At least a portion of the functional layers OL1 and OL2 unstably arranged on the first space A1 in the peripheral opening OH-NPX may be disconnected. At least a portion of the functional layers OL1 and OL2 may have a shape cut into a plurality of portions, in a vertical or horizontal direction, spaced and/or apart (e.g., spaced apart or separated) by as much as the second space A2 and separated from each other. The second space A2 may refer to an air gap which is penetrated by the functional layers OL1 and OL2 arranged in the peripheral opening OH-NPX. The second space A2 may refer to a spacing space between second functional parts OL1-2 and OL2-2 to be described in more detail later.

The functional layers OL1 and OL2 may include first functional parts OL1-1 and OL2-1 overlapping the pixel regions PXA1 and PXA2 and the second functional parts OL1-2 and OL2-2 overlapping the peripheral region NPXA. At least a portion of the second functional parts OL1-2 and OL2-2 overlapping the peripheral region NPXA may be cut by the air gap AG. A first functional layer OL1 of a first light-emitting element OLED1 may include a (1-1)-th functional part OL1-1 overlapping the first pixel region PXA1 and a (1-2)-th functional part OL1-2 overlapping the peripheral region NPXA, and a second functional layer OL2 of a second light-emitting element OLED2 may include a (2-1)-th functional part OL2-1 overlapping the second pixel region PXA2 and a (2-2)-th functional part OL2-2 overlapping the peripheral region NPXA. Here, the (1-2)-th functional part OL1-2 and the (2-2)-th functional part OL2-2 may be spaced and/or apart (e.g., spaced apart or separated) by the second space A2.

Compared to FIG. 7B, in FIG. 8, a portion of not only the functional layers OL1 and OL2 but also the second electrodes CE1 and CE2 may be cut in the peripheral region NPXA by an air gap AG-a. Even if a portion of the second electrodes CE1 and CE2 is cut in the peripheral region NPXA, another portion of the second electrodes CE1 and CE2 is not cut, and thus the second electrodes CE1 and CE2 may be provided as a common layer in the pixel regions PXA-R, PXA-G, and PXA-B (see FIG. 6) overall.

The air gap AG-a may include a first space A1 and a second space A2 and may further include a third space A3. At least a portion of the second electrodes CE1 and CE2 unstably arranged on the second space A2 in a peripheral opening OH-NPX may be disconnected. At least a portion of the second electrodes CE1 and CE2 may have a shape cut into a plurality of portions, in a vertical or horizontal direction, spaced and/or apart (e.g., spaced apart or separated) by as much as the third space A3 and separated from each other. The third space A3 may refer to an air gap which is penetrated by the second electrodes CE1 and CE2 arranged in the peripheral opening OH-NPX. The third space A3 may refer to a spacing space between second electrode portions CE1-2 and CE2-2 to be described in more detail later.

The second electrode CE1 of the first light-emitting element OLED1 may include a (1-1)-th electrode portion CE1-1 overlapping the first pixel region PXA1 and a (1-2)-th electrode portion CE1-2 overlapping the peripheral region NPXA, and the second electrode CE2 of the second light-emitting element OLED2 may include a (2-1)-th electrode portion CE2-1 overlapping the second pixel region PXA2 and a (2-2)-th electrode portion CE2-2 overlapping the peripheral region NPXA. Here, the (1-2)-th electrode portion CE1-2 and the (2-2)-th electrode portion CE2-2 may be spaced and/or apart (e.g., spaced apart or separated) by the third space A3.

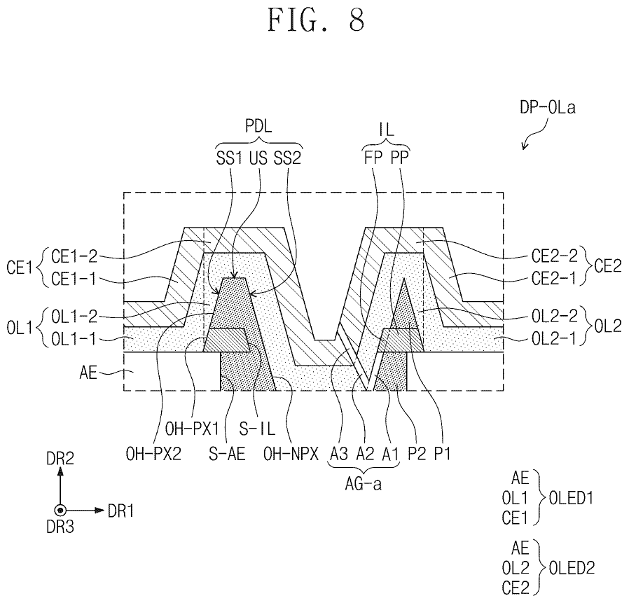

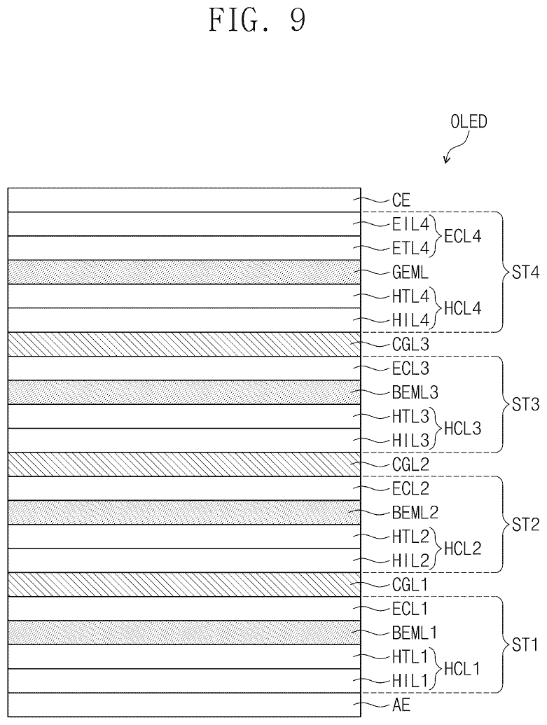

FIG. 9 is a cross-sectional view of a light-emitting element according to one or more embodiments of the present disclosure. FIG. 9 illustrates a light-emitting element OLED including a plurality of stacks ST1, ST2, ST3, and ST4 unlike the light-emitting element of one or more embodiments illustrated in FIGS. 5 to 8.

Referring to FIG. 9, the light-emitting element OLED of one or more embodiments may include a first electrode AE, a second electrode CE opposite to (e.g., facing) the first electrode AE, and first to fourth light-emitting stacks ST1, ST2, ST3, and ST4 arranged between the first electrode AE and the second electrode CE. In one or more embodiments, FIG. 9 illustrates that the light-emitting element OLED includes four light-emitting stacks, but the number of light-emitting stacks included in the light-emitting element OLED may be fewer or more than four.

The light-emitting element OLED may include first to third charge generation layers CGL1, CGL2, and CGL3 arranged between the first to fourth light-emitting stacks ST1, ST2, ST3, and ST4.

When a voltage is applied to the first to third charge generation layers CGL1, CGL2, and CGL3, the first to third charge generation layers CGL1, CGL2, and CGL3 may generate charges (electrons and holes) by forming a complex through oxidation-reduction reaction. Thereafter, the first to third charge generation layers CGL1, CGL2, and CGL3 may provide the generated charges to adjacent stacks ST1, ST2, ST3, and ST4. The first to third charge generation layers CGL1, CGL2, and CGL3 may double or improve an efficiency of a current generated in the adjacent stacks ST1, ST2, ST3, and ST4 and may serve to adjust balance of the charges between the adjacent stacks ST1, ST2, ST3, and ST4.

The first to third charge generation layers CGL1, CGL2, and CGL3 may each include an n-type (kind) layer and a p-type (kind) layer. The first to third charge generation layers CGL1, CGL2, and CGL3 may have a structure in which an n-type (kind) layer and a p-type (kind) layer are bonded to each other. However, one or more embodiments of the present disclosure is not limited thereto, and the first to third charge generation layers CGL1, CGL2, and CGL3 may include only one of an n-type (kind) layer or a p-type (kind) layer. The n-type (kind) layer may be a charge generation layer which provides an electron to an adjacent stack. The n-type (kind) layer may be a layer in which a base material is doped with an n-dopant. The p-type (kind) layer may be a charge generation layer which provides a hole to an adjacent stack.

In one or more embodiments, a thickness of each of the first to third charge generation layers CGL1, CGL2, and CGL3 may be about 1 angstrom to about 150 angstroms. A concentration of an n-dopant with which the first to third charge generation layers CGL1, CGL2, and CGL3 are doped may be about 0.1% to about 3% and, for example, may be about 1% or less. In a case in which the concentration is less than about 0.1%, an effect of the first to third charge generation layers CGL1, CGL2, and CGL3, which adjust balance of the charges, may hardly occur or the occurrences may be reduced. In a case in which the concentration is more than about 3%, light efficiency of the light-emitting element OLED may be deteriorated or reduced.

The first to third charge generation layers CGL1, CGL2, and CGL3 may each include a charge generation compound including an aryl amine-based organic compound, metal, metal oxide, carbide, fluoride, and/or a (e.g., any suitable) mixture thereof. For example, the aryl amine-based organic compound may include α-NPD, 2-TNATA, TDATA, MTDATA, sprio-TAD, or sprio-NPB. The metal may include cesium (Cs), molybdenum (Mo), vanadium (V), titanium (Ti), tungsten (W), barium (Ba), or lithium (Li). The metal oxide, carbide, and fluoride may include Re₂O₇, MoO₃, V₂O₅, WO₃, TiO₂, CS₂CO₃, BaF, LiF, or CsF. However, materials of the first to third charge generation layers CGL1, CGL2, and CGL3 are not limited to these examples.

The first to fourth light-emitting stacks ST1, ST2, ST3, and ST4 may each include an emission layer. The first light-emitting stack ST1 may include a first emission layer BEML1, the second light-emitting stack ST2 may include a second emission layer BEML2, the third light-emitting stack ST3 may include a third emission layer BEML3, and the fourth light-emitting stack ST4 may include a fourth emission layer GEML. Some of the emission layers included in the first to fourth light-emitting stacks ST1, ST2, ST3, and ST4 may be configured to emit the same (e.g., substantially the same) color light, and others may be configured to emit different color light.

In one or more embodiments, the first to third emission layers BEML1, BEML2, and BEML3 of the first to third light-emitting stacks ST1, ST2, and ST3 may be configured to emit substantially the same first color light. For example, the first color light may be blue light that is the source light described above. A wavelength range of light which is emitted by the first to third emission layers BEML1, BEML2, and BEML3 may be about 420 nm to about 480 nm.

The fourth emission layer GEML of the fourth light-emitting stack ST4 may be configured to emit second color light different from the first color light. For example, the second color light may be green light. A wavelength range of light which is emitted by the fourth emission layer GEML may be about 520 nm to about 600 nm.

The light-emitting element OLED may be configured to emit light in a direction from the first electrode AE to the second electrode CE. In the light-emitting element OLED of one or more embodiments, the plurality of stacks ST1, ST2, ST3, and ST4 may include hole transport regions HCL1, HCL2, HCL3, and HCL4 and electron transport regions ECL1, ECL2, ECL3, and ECL4. The hole transport regions HCL1, HCL2, HCL3, and HCL4 may transfer holes that are provided from the first electrode AE or the charge generation layers CGL1, CGL2, and CGL3 to the emission layer. The electron transport regions ECL1, ECL2, ECL3, and ECL4 may transfer electrons that are provided from the second electrode CE or the charge generation layers CGL1, CGL2, and CGL3 to the emission layer.

It is illustrated that, with respect to a direction in which light is emitted, the light-emitting element OLED of one or more embodiments has a structure in which the hole transport regions HCL1, HCL2, HCL3, and HCL4 are arranged below the emission layers BEML-1, BEML-2, BEML-3, and GEML included in the plurality of stacks ST1, ST2, ST3, and ST4, and the electron transport regions ECL1, ECL2, ECL3, and ECL4 are arranged above the emission layers BEML-1, BEML-2, BEML-3, and GEML included in the plurality of stacks ST1, ST2, ST3, and ST4. For example, the light-emitting element OLED of one or more embodiments may have a forward element structure. However, one or more embodiments of the present disclosure is not limited thereto, and with respect to a direction in which light is emitted, the light-emitting element OLED may have an inverted element structure in which the electron transport regions ECL1, ECL2, ECL3, and ECL4 are arranged below the emission layers BEML-1, BEML-2, BEML-3, and GEML included in the plurality of stacks ST1, ST2, ST3, and ST4, and the hole transport regions HCL1, HCL2, HCL3, and HCL4 are arranged above the emission layers BEML-1, BEML-2, BEML-3, and GEML included in the plurality of stacks ST1, ST2, ST3, and ST4.

The hole transport regions HCL1, HCL2, HCL3, and HCL4 may include hole injection layers HIL1, HIL2, HIL3, and HIL4 and hole transport layers HTL1, HTL2, HTL3, and HTL4 arranged on the hole injection layers HIL1, HIL2, HIL3, and HIL4, respectively. The hole transport layers HTL1, HTL2, HTL3, and HTL4 may be in contact with a lower surface of the emission layer. However, one or more embodiments of the present disclosure is not limited thereto, and the hole transport regions HCL1, HCL2, HCL3, and HCL4 may further include a hole-side additional layer arranged on the hole transport layers HTL1, HTL2, HTL3, and HTL4. The hole-side additional layer may include at least one of a hole buffer layer, an emission auxiliary layer, or an electron blocking layer. The hole buffer layer may be a layer which compensates for a resonance distance according to a wavelength of light that is emitted from an emission layer and increases light emission efficiency. The electron blocking layer may be a layer which serves to prevent or reduce an electron from being injected from an electron transport region to a hole transport region.

The electron transport regions ECL1, ECL2, ECL3, and ECL4 may include an electron transport layer. The electron transport regions ECL1, ECL2, ECL3, and ECL4 may further include an electron injection layer arranged on the electron transport layer. For example, a fourth electron transport region ECL4 included in the fourth light-emitting stack ST4 may further include a fourth electron injection layer EIL4 arranged on a fourth electron transport layer ETL4. The electron transport regions ECL1, ECL2, ECL3, and ECL4 may further include an electron-side additional layer arranged between an electron transport layer and an emission layer. The electron-side additional layer may include at least one of an electron buffer layer or a hole blocking layer.

Because a side surface of an inorganic layer is exposed by a peripheral opening, driving error or current leakage between light-emitting regions adjacent to each other may be prevented or reduced, and thus a display panel according to one or more embodiments of the present disclosure may have improved reliability. In a case in which a display panel includes a plurality of light-emitting regions in which light having different colors is emitted and at the same time a light-emitting element is arranged in common in the plurality of light-emitting regions, lateral leakage current may occur. For example, in a case in which the light-emitting element includes a plurality of light-emitting stacks and a charge generation layer, a charge of the charge generation layer may be transferred to an adjacent pixel, and in the display panel according to one or more embodiments of the present disclosure, because at least a portion of a functional layer is short-circuited, the charge generation layer may be short-circuited, and thus color mixing may be prevented or reduced. However, the display panel according to one or more embodiments of the present disclosure may include a protruding portion of the inorganic layer protruding from a side surface of a pixel-defining film in a peripheral region, and thus may have an undercut shape, and an emission functional layer arranged as a common layer may be disconnected by an air gap, which makes it possible for each of light-emitting elements to be driven and to be configured to emit light independently. Thus, the display panel may have improved color reproducibility. In addition, because the emission functional layer is disconnected in the peripheral region, dark spot may be reduced compared to a case in which the emission functional layer is disconnected in a display region, and thus the display panel according to one or more embodiments of the present disclosure may have improved display quality. In addition, disconnection of the emission functional layer may be implemented using a pixel-defining film which is a component of a typical display panel, and thus an effect of applying one or more embodiments of the present disclosure to a high-resolution display panel having a small peripheral region and a pixel region may be exhibited.

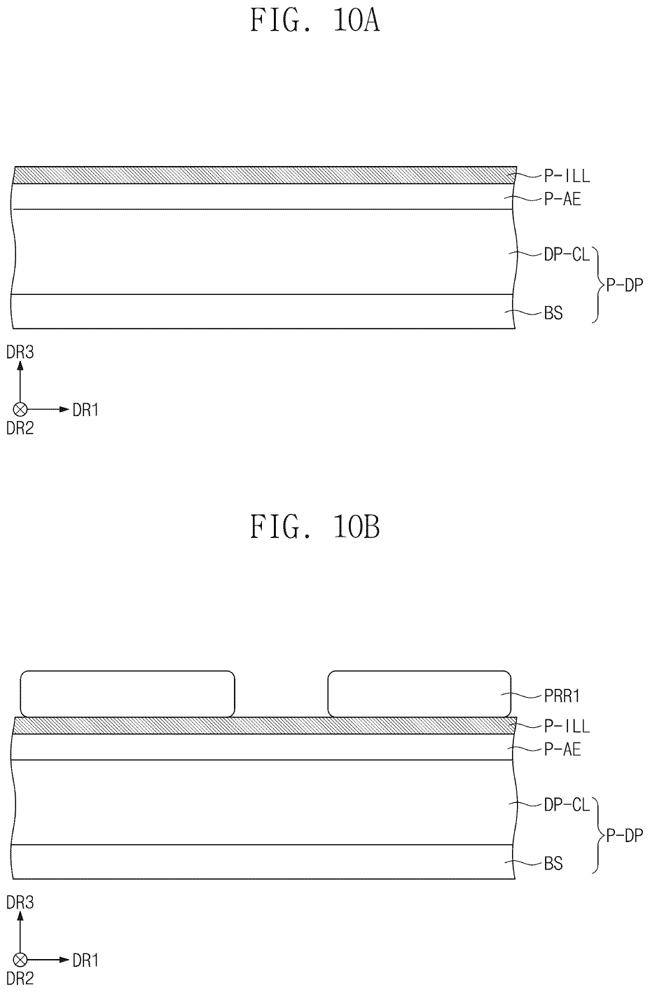

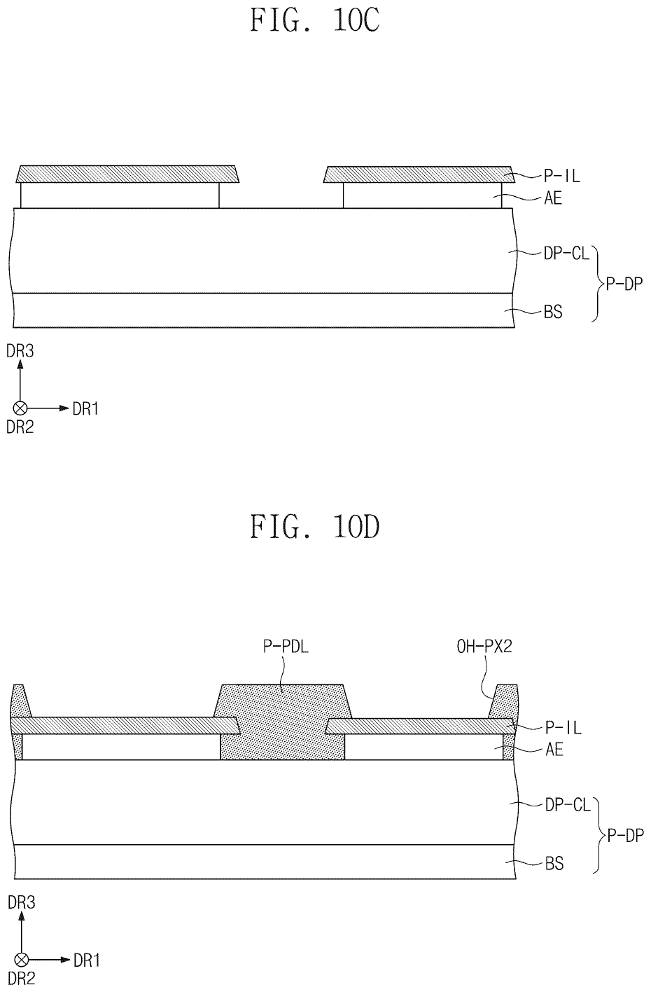

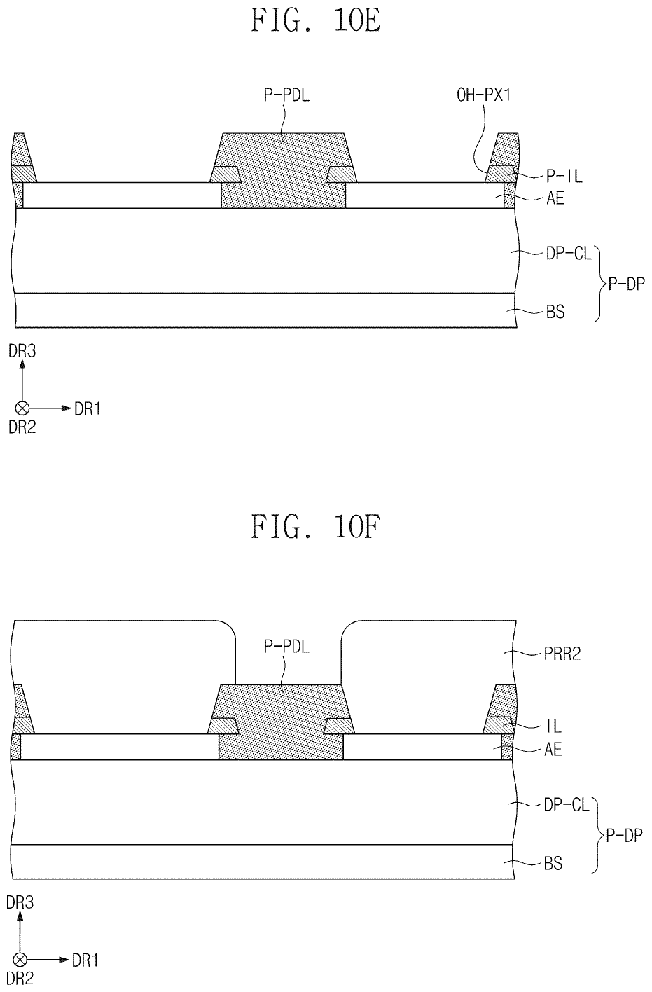

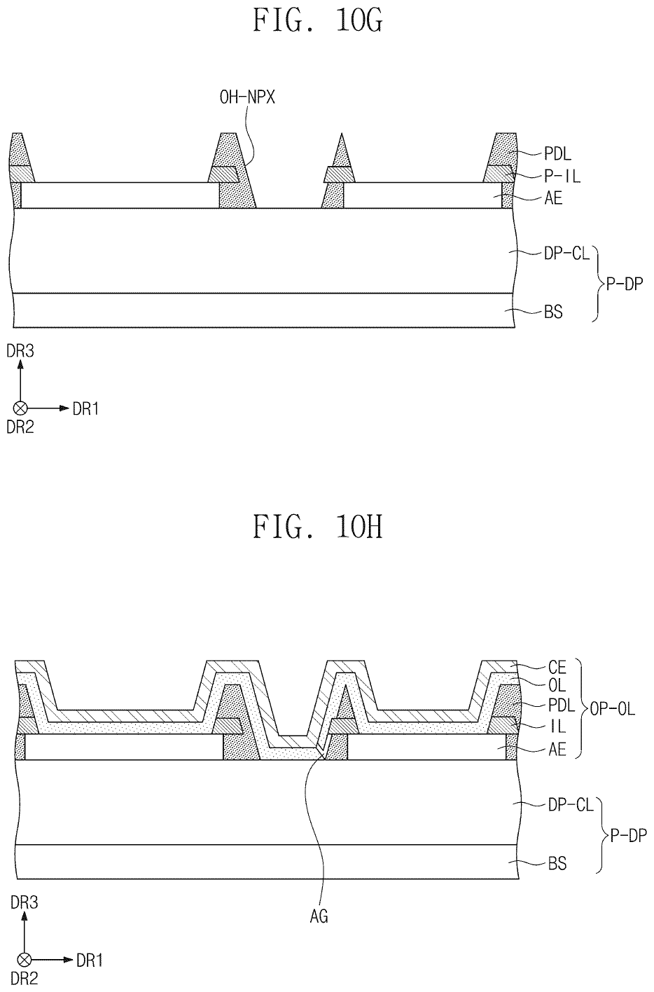

FIGS. 10A to 10H are cross-sectional views illustrating some steps (e.g., acts or tasks) of a manufacturing method of a display panel according to one or more embodiments of the present disclosure. FIGS. 10A to 10H illustrates a cross section in some steps of a manufacturing method of a display panel based on a cross-sectional view corresponding to FIG. 7A. In one or more embodiments, in describing a manufacturing method of a display panel according to one or more embodiments of the present disclosure, a component being the same as the component described above will be denoted by the same reference numerals or symbols, and detailed description thereof will not be provided.

Referring to FIG. 10A, a manufacturing method of a display panel according to one or more embodiments of the present disclosure includes providing a preliminary display substrate P-DP. The preliminary display substrate P-DP includes a base substrate BS and a circuit layer DP-CL arranged on the base substrate.

The manufacturing method of a display panel according to one or more embodiments of the present disclosure includes, after the providing of the preliminary display substrate P-DP, forming a preliminary electrode P-AE and a first preliminary inorganic layer P-ILL on the preliminary display substrate P-DP. The preliminary electrode P-AE and the first preliminary inorganic layer P-ILL may be formed so as to overlap (e.g., entirely overlap) an upper surface of the preliminary display substrate P-DP. The preliminary electrode P-AE may include (e.g., may be formed of) a metal material, metal alloy, or conductive compound. The preliminary electrode P-AE may include the same material as a material included in the first electrode AE (see FIG. 5) described above. For example, the preliminary electrode P-AE and the first electrode AE (see FIG. 5) described above may include or be of the same material. The first preliminary inorganic layer P-ILL may include silicon nitride (SiNₓ), silicon oxide (SiOₓ), silicon oxynitride (SiOₓN_{y}), and/or the like. The first preliminary inorganic layer P-ILL may include the same material as a material included in the inorganic layer IL (see FIG. 5) described above. For example, the first preliminary inorganic layer P-ILL and the inorganic layer IL (see FIG. 5) described above may include or be of the same material.

Referring to FIGS. 10B and 10C, the manufacturing method of a display panel according to one or more embodiments of the present disclosure may include, after the forming of the preliminary electrode P-AE and the first preliminary inorganic layer P-ILL on the preliminary display substrate P-DP, arranging a first photoresist pattern PRR1 on the first preliminary inorganic layer P-ILL, forming a second preliminary inorganic layer P-IL by dry etching the first preliminary inorganic layer P-ILL, and forming a first electrode AE by wet etching the preliminary electrode P-AE.

The first photoresist pattern PRR1 may function as a mask in dry etching the first preliminary inorganic layer P-ILL and in wet etching the preliminary electrode P-AE. The first photoresist pattern PRR1 may be arranged on the preliminary display substrate P-DP in correspondence to the pixel region PXA (see FIG. 7A). In one or more embodiments, the arranging of the first photoresist pattern PRR1 may include forming a photoresist layer by applying a photoresist material onto the preliminary display substrate P-DP and then forming the first photoresist pattern PRR1 by patterning the photoresist layer through an exposure process.

The first preliminary inorganic layer P-ILL may be removed through a dry etching process by etching gas. A remaining portion, of the first preliminary inorganic layer P-ILL, not covered with the first photoresist pattern PRR1 may be etched. The first preliminary inorganic layer P-ILL may be etched by anisotropic etching.

The preliminary electrode P-AE may be removed through a wet etching process by etchant. A remaining portion, of the preliminary electrode P-AE, not covered with the first photoresist pattern PRR1 may be etched. The preliminary electrode P-AE may be etched by isotropic etching. Accordingly, the preliminary electrode P-AE may include an undercut shape because the preliminary electrode P-AE may be etched also in a horizontal direction below the first photoresist pattern PRR1 and the dry-etched first preliminary inorganic layer P-ILL.

Referring to FIG. 10D, the manufacturing method of a display panel according to one or more embodiments of the present disclosure may include, after the forming of the second preliminary inorganic layer P-IL and the forming of the first electrode AE, forming a preliminary pixel-defining film P-PDL.

The preliminary pixel-defining film P-PDL may be formed on the circuit layer DP-CL in correspondence to the peripheral region NPXA (see FIG. 7A). A second pixel opening OH-PX2 may be defined in the preliminary pixel-defining film P-PDL in correspondence to the pixel region PXA (see FIG. 7A). A portion of an upper surface of the second preliminary inorganic layer P-IL may be exposed by the second pixel opening OH-PX2. The preliminary pixel-defining film P-PDL may include an organic material. For example, the preliminary pixel-defining film P-PDL may include a polyacrylate-based resin or a polyimide-based resin. The preliminary pixel-defining film P-PDL may include the same material as a material included in the pixel-defining film PDL (see FIG. 7A). For example, the preliminary pixel-defining film P-PDL and the pixel-defining film PDL (see FIG. 7A) may include or be of the same material.

Referring to FIG. 10E, the manufacturing method of a display panel according to one or more embodiments of the present disclosure may include, after the forming of the preliminary pixel-defining film P-PDL, forming an inorganic layer IL.

The inorganic layer IL may be formed by defining a first pixel opening OH-PX1 in the second preliminary inorganic layer P-IL (see FIG. 10D). The first pixel opening OH-PX1 of the inorganic layer IL may be formed by dry etching a portion of the second preliminary inorganic layer P-IL so as to correspond to the second pixel opening OH-PX2 (see FIG. 10D) of the preliminary pixel-defining film P-PDL.

Referring to FIGS. 10F and 10G, the manufacturing method of a display panel according to one or more embodiments of the present disclosure may include, after the forming of the inorganic layer IL, arranging a second photoresist pattern PRR2 on the inorganic layer IL and forming a pixel-defining film PDL by dry etching the preliminary pixel-defining film P-PDL.

The second photoresist pattern PRR2 may function as a mask in dry etching the preliminary pixel-defining film P-PDL. The second photoresist pattern PRR2 may be arranged on the preliminary pixel-defining film P-PDL and the first electrode AE in correspondence to a peripheral opening OH-NPX to be formed. In one or more embodiments, the arranging of the second photoresist pattern PRR2 may include forming a photoresist layer by applying a photoresist material onto the preliminary pixel-defining film P-PDL and the first electrode AE and then forming the second photoresist pattern PRR2 by patterning the photoresist layer through an exposure process.

The preliminary pixel-defining film P-PDL may be removed through a dry etching process by etching gas. A remaining portion, of the preliminary pixel-defining film P-PDL, not covered with the second photoresist pattern PRR2 may be etched. The preliminary pixel-defining film P-PDL may be etched by anisotropic etching. The etched preliminary pixel-defining film P-PDL may be defined as the peripheral opening OH-NPX.

The inorganic layer IL may include an inorganic material, and the preliminary pixel-defining film P-PDL may include an organic material. In a case in which the inorganic layer IL includes an inorganic material whereas the preliminary pixel-defining film P-PDL includes an organic material, etch rate of the inorganic layer IL and etch rate of the preliminary pixel-defining film P-PDL may be different in etching a portion of the preliminary pixel-defining film P-PDL. Accordingly, at least a portion of a side surface of the inorganic layer IL may be exposed by the peripheral opening OH-NPX. For example, even if there is a portion of the inorganic layer IL not covered with the second photoresist pattern PRR2, a degree to which the portion of the inorganic layer IL is etched is not high compared to that of the preliminary pixel-defining film P-PDL, and thus the inorganic layer IL may have a relatively protruding shape.

Referring to FIG. 10H, the manufacturing method of a display panel according to one or more embodiments of the present disclosure may include, after the forming of the pixel-defining film PDL, forming a display element layer DP-OL by forming an functional layer OL and a second electrode CE in the first and second pixel openings OH-PX1 and OH-PX2 and the peripheral opening OH-NPX. In forming the functional layer OL, an air gap AG may be formed due to an undercut structure under the inorganic layer IL.

A display panel of one or more embodiments may have a structure in which a peripheral opening of a pixel-defining film is defined in a peripheral region adjacent to a pixel region and a side surface, of an inorganic layer arranged on a first electrode, in the peripheral opening is exposed, and thus deterioration of display quality may be suppressed or reduced, and the display panel may exhibit excellent or suitable reliability.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The utilization of “may” when describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although description has been made with reference to one or more embodiments of the present disclosure, it is understood that the present disclosure should not be limited to these embodiments, but one or more suitable changes and modifications may be made by one ordinary skilled in the art within the spirit and scope of the present disclosure as hereinafter claimed.

Therefore, the technical scope of the present disclosure is not limited to the contents described in the detailed description of the specification, but should be determined by the accompanying claims.

What is claimed is:

1. A display panel comprising:
a base substrate comprising a pixel region and a peripheral region adjacent to the pixel region;
a circuit layer on the base substrate; and
a display element layer on the circuit layer,
wherein the display element layer comprises
an inorganic layer having a first pixel opening overlapping the pixel region,
a pixel-defining film comprising a second pixel opening corresponding to the first pixel opening and a peripheral opening overlapping the peripheral region, and at least a portion of the pixel-defining film being on the inorganic layer, and
a light-emitting element comprising a first electrode under the inorganic layer and at least a portion of an upper surface of the light-emitting element being exposed by the first pixel opening, a functional layer in the first pixel opening and the second pixel opening, and a second electrode on the functional layer,
wherein the pixel-defining film comprises an upper surface, a first side surface extending from the upper surface and defining the second pixel opening, and a second side surface opposite to the first side surface and defining the peripheral opening, and
at least a portion of the inorganic layer protrudes from the second side surface to an inner side of the peripheral opening.

2. The display panel of claim 1, wherein the functional layer is in the peripheral opening.

3. The display panel of claim 2, wherein at least a portion of the functional layer is cut in the peripheral region.

4. The display panel of claim 1, wherein at least a portion of a side surface of the inorganic layer is exposed by the peripheral opening.

5. The display panel of claim 1, wherein at least a portion of an upper surface of the circuit layer is exposed by the peripheral opening.

6. The display panel of claim 1, wherein the inorganic layer comprises silicon nitride.

7. The display panel of claim 1, wherein at least a portion of the inorganic layer overlaps the peripheral opening in a plan view.

8. The display panel of claim 1, wherein the pixel-defining film comprises a first portion and a second portion below the first portion, and the first portion and the second portion are spaced from each other with the inorganic layer therebetween in a cross-sectional view.

9. The display panel of claim 8, wherein the first portion is directly on the inorganic layer.

10. The display panel of claim 8, wherein the second portion is on the same layer as the first electrode.

11. The display panel of claim 8, wherein the inorganic layer comprises a protruding portion protruding from the second side surface and a flat portion between the first portion and the second portion.

12. The display panel of claim 1, wherein the functional layer comprises a first functional part overlapping the pixel region and a second functional part overlapping the peripheral region, and
at least a portion of the second functional part is cut by an air gap.

13. The display panel of claim 12, wherein the second functional part and the pixel-defining film are spaced from each other with the air gap therebetween.

14. The display panel of claim 12, wherein the pixel region comprises a first pixel region and a second pixel region spaced from each other with the peripheral region therebetween in a plan view,
the light-emitting element comprises a first light-emitting element overlapping the first pixel region and comprising a first functional layer, and a second light-emitting element overlapping the second pixel region and comprising a second functional layer,
the first functional layer comprises a (1-1)-th functional part overlapping the first pixel region and a (1-2)-th functional part overlapping the peripheral region and extending from the (1-1)-th functional part, and the second functional layer comprises a (2-1)-th functional part overlapping the second pixel region and a (2-2)-th functional part overlapping the peripheral region and extending from the (2-1)-th functional part, and
the (1-2)-th functional part and the (2-2)-th functional part are spaced apart with the air gap therebetween.

15. The display panel of claim 1, wherein the light-emitting element is configured to emit source light, and
the display panel further comprises an optical structure layer that is on the display element layer and is configured to transmit the source light or is configured to convert the source light into light of a different wavelength.

16. The display panel of claim 15, wherein the optical structure layer comprises a light control layer comprising a light control pattern, and a color filter layer on the light control layer and comprising a color filter.

17. A manufacturing method comprising:
providing a preliminary display substrate comprising a base substrate comprising a pixel region and a peripheral region adjacent to the pixel region and a circuit layer on the base substrate;
forming a preliminary electrode and a first preliminary inorganic layer on the preliminary display substrate;
arranging a first photoresist pattern on the first preliminary inorganic layer;
forming a second preliminary inorganic layer by etching a portion of the first preliminary inorganic layer;
forming a first electrode by etching a portion of the preliminary electrode;
forming a preliminary pixel-defining film on the circuit layer in correspondence to the peripheral region;
forming an inorganic layer by forming a first pixel opening overlapping the pixel region by etching a portion of the second preliminary inorganic layer;
arranging a second photoresist pattern on the preliminary pixel-defining film; and
forming a pixel-defining film by forming a peripheral opening by etching a portion of the preliminary pixel-defining film,
wherein the peripheral opening exposes at least a portion of a side surface of the inorganic layer, and
wherein the manufacturing method is a manufacturing method of a display panel.

18. The manufacturing method of claim 17, wherein the inorganic layer comprises an inorganic material, and the pixel-defining film comprises an organic material.

19. The manufacturing method of claim 17, wherein the forming of the second preliminary inorganic layer, the forming of the inorganic layer by forming the first pixel opening, and the forming of the pixel-defining film comprise a dry etching process.

20. An electronic device providing an image,
the electronic device comprising:
a window;
a display panel below the window; and
a housing below the display panel and coupled with the window to accommodate the display panel,
the display panel comprising:
a base substrate comprising a pixel region and a peripheral region adjacent to the pixel region;
a circuit layer on the base substrate; and
a display element layer on the circuit layer,
wherein the display element layer comprises
an inorganic layer having a first pixel opening overlapping the pixel region,
a pixel-defining film comprising a second pixel opening corresponding to the first pixel opening and a peripheral opening overlapping the peripheral region, and at least a portion of the pixel-defining film being on the inorganic layer, and
a light-emitting element comprising a first electrode under the inorganic layer and at least a portion of an upper surface of the light-emitting element being exposed by the first pixel opening, a functional layer in the first pixel opening and the second pixel opening, and a second electrode on the functional layer,
wherein the pixel-defining film comprises an upper surface, a first side surface extending from the upper surface and defining the second pixel opening, and a second side surface opposite to the first side surface and defining the peripheral opening, and
at least a portion of the inorganic layer protrudes from the second side surface to an inner side of the peripheral opening.
